(19) United States
(12) Patent Application Publication
(10) Pub. No.: US 2025/0023329 A1
(43) Pub. Date: Jan. 16, 2025

(54) SURFACE EMITTING ELEMENT AND INDIVIDUAL AUTHENTICATION DEVICE

(71) Applicant: SONY GROUP CORPORATION, TOKYO (JP)

(72) Inventors: KENTARO HAYASHI, TOKYO (JP); TATSUSHI HAMAGUCHI, TOKYO (JP); EIJI NAKAYAMA, TOKYO (JP); TATSUROU SATOU, TOKYO (JP); HIDEKAZU KAWANISHI, TOKYO (JP); RINTARO KODA, TOKYO (JP)

(21) Appl. No.: 18/715,509

(22) PCT Filed: Oct. 27, 2022
(86) PCT No.: PCT/JP2022/040093

§ 371 Date: May 31, 2024

(30) Foreign Application Priority Data
Dec. 7, 2021 (JP) 2021-198567

(51) Int. Cl. H01S 5/183

(52) U.S. Cl. CPC H01S 5/18369

(57) ABSTRACT

Provided is a surface emitting element capable of imparting a special characteristic to an element portion. A surface emitting element according to the present technology provides a surface emitting element including at least one element portion including: a light emitting layer; and a concave mirror disposed on one side of the light emitting layer, in which the concave mirror includes: a concave mirror body; and a structure including a protrusion or a recess. According to the present technology, it is possible to provide a surface emitting element capable of imparting a special characteristic to an element portion.

### TECHNICAL FIELD

The technology according to the present disclosure (hereinafter also referred to as “the present technology”) relates to a surface emitting element and an individual authentication device.

### BACKGROUND ART

Conventionally, a surface emitting element including an element portion including a light emitting layer and a concave mirror has been known (see, for example, Patent Document 1).

### CITATION LIST

### Patent Document

Patent Document 1: WO 2018/083877 A

### SUMMARY OF THE INVENTION

### Problems to be Solved by the Invention

However, in the conventional surface emitting element, there is room for improvement regarding giving special characteristics to the element portion.

Therefore, a main object of the present technology is to provide a surface emitting element capable of imparting a special characteristic to an element portion.

### Solutions to Problems

The present technology provides a surface emitting element including
at least one element portion including:
a light emitting layer; and
a concave mirror disposed on one side of the light emitting layer,
in which the concave mirror includes:
a concave mirror body; and
a structure including a protrusion or a recess.

The element portion may further include a reflector disposed on another side of the light emitting layer.

The structure may be smaller than the concave mirror body.

The structure may have a curvature.

The structure may be provided at least on a surface of the concave mirror body farthest from the light emitting layer.

The structure may be provided at least on a surface of the concave mirror body closest to the light emitting layer.

A plurality of the structures may be disposed in an in-plane direction of the concave mirror body.

A plurality of the structures may be disposed in a thickness direction of the concave mirror body.

The concave mirror body and the structure may be integrated.

The concave mirror body and the structure may be separate bodies.

The element portion may further include an intermediate layer disposed between the concave mirror and the light emitting layer, and the intermediate layer may have a convex surface structure corresponding to the concave mirror on a surface on a side of the concave mirror.

A portion of the convex surface structure corresponding to the concave mirror body and a portion of the convex surface structure corresponding to the structure may be separate bodies.

The concave mirror may have an adhesive layer provided with the structure between the concave mirror body and the convex surface structure.

The structure may be disposed at a position on an optical path of light from the light emitting layer.

The structure may be disposed at a position deviated from an optical path of light from the light emitting layer.

The concave mirror may have a plurality of the structures, and the plurality of the structures may include: the structure disposed at a position on an optical path of light from the light emitting layer; and the structure disposed at a position deviated from an optical path of light from the light emitting layer.

A plurality of the element portions may be arranged in an array, and the plurality of the element portions may include at least two element portions having different numbers of the structures.

An element portion having the largest number of the structures among the at least two element portions may be arranged on an outer peripheral side of the array, and an element portion having the smallest number of the structures may be arranged on an inner peripheral side of the array.

A plurality of the structures may be provided in the concave mirror body in an array.

The present technology also provides an individual authentication device including: the surface emitting element according to claim 1 in which a pattern formed by emitted light is assigned to an individual; and a processing section that receives light from the surface emitting element and performs individual authentication.

### BRIEF DESCRIPTION OF DRAWINGS

FIG. 1 is a cross-sectional view of a surface emitting element according to Example 1 of an embodiment of the present technology.

FIG. 2 is a plan view of a concave mirror of the surface emitting element of FIG. 1.

FIG. 3 is a flowchart for explaining an example of a method for manufacturing the surface emitting element in FIG. 1.

FIG. 4 is a flowchart for explaining a protruding convex surface structure forming process 1.

FIGS. 5A and 5B are cross-sectional views for each step of the method for manufacturing the surface emitting element in FIG. 1.

FIGS. 6A to 6C are cross-sectional views for each step of the method for manufacturing the surface emitting element in FIG. 1.

FIGS. 7A and 7B are cross-sectional views for each step of the method for manufacturing the surface emitting element in FIG. 1.

FIGS. 8A and 8B are cross-sectional views for each step of the method for manufacturing the surface emitting element in FIG. 1.

FIGS. 9A and 9B are cross-sectional views for each step of the method for manufacturing the surface emitting element in FIG. 1.

FIG. 10 is a cross-sectional view of a surface emitting element according to Example 2 of an embodiment of the present technology.

FIG. 11 is a cross-sectional view of a surface emitting element according to Example 3 of an embodiment of the present technology.

FIG. 12 is a cross-sectional view of a surface emitting element according to Example 4 of an embodiment of the present technology.

FIG. 13 is a flowchart for explaining a protruding convex surface structure forming process 2.

FIGS. 14A and 14B are cross-sectional views for each step of the method for manufacturing the surface emitting element in FIG. 12.

FIGS. 15A and 15B are cross-sectional views for each step of the method for manufacturing the surface emitting element in FIG. 12.

FIGS. 16A and 16B are cross-sectional views for each step of the method for manufacturing the surface emitting element in FIG. 12.

FIG. 17 is a flowchart for explaining a protruding convex surface structure forming process 3.

FIG. 18 is a flowchart for explaining a protruding convex surface structure forming process 4.

FIG. 19 is a flowchart for explaining a protruding convex surface structure forming process 5.

FIG. 20 is a cross-sectional view of a surface emitting element according to Example 5 of an embodiment of the present technology.

FIG. 21 is a plan view of a concave mirror of the surface emitting element of FIG. 20.

FIG. 22 is a cross-sectional view of a surface emitting element according to Example 6 of an embodiment of the present technology.

FIG. 23 is a plan view of a concave mirror of the surface emitting element of FIG. 22.

FIG. 24 is a cross-sectional view of a surface emitting element according to Example 7 of an embodiment of the present technology.

FIG. 25 is a cross-sectional view of a surface emitting element according to Example 8 of an embodiment of the present technology.

FIG. 26 is a plan view of a concave mirror of the surface emitting element of FIG. 25.

FIG. 27 is a cross-sectional view of a surface emitting element according to Example 9 of an embodiment of the present technology.

FIG. 28 is a cross-sectional view of a surface emitting element according to Example 10 of an embodiment of the present technology.

FIG. 29 is a plan view of a surface emitting element according to Example 11 of an embodiment of the present technology.

FIG. 30 is a cross-sectional view taken along line P-P in FIG. 29.

FIG. 31 is a cross-sectional view of a surface emitting element according to Example 12 of an embodiment of the present technology.

FIG. 32 is a cross-sectional view of a surface emitting element according to Example 13 of an embodiment of the present technology.

FIG. 33 is a plan view of a surface emitting element according to Example 14 of an embodiment of the present technology.

FIG. 34 is a cross-sectional view taken along line Q-Q in FIG. 33.

FIG. 35 is a cross-sectional view of a surface emitting element according to Example 15 of an embodiment of the present technology.

FIG. 36 is a flowchart for explaining an example of a method for manufacturing the surface emitting element of FIG. 35.

FIGS. 37A and 37B are cross-sectional views for each step of the method for manufacturing the surface emitting element in FIG. 35.

FIGS. 38A and 38B are cross-sectional views for each step of the method for manufacturing the surface emitting element in FIG. 35.

FIGS. 39A and 39B are cross-sectional views for each step of the method for manufacturing the surface emitting element in FIG. 35.

FIGS. 40A and 40B are cross-sectional views for each step of the method for manufacturing the surface emitting element in FIG. 35.

FIG. 41 is a cross-sectional view of a surface emitting element according to Example 16 of an embodiment of the present technology.

FIG. 42 is a cross-sectional view of a surface emitting element according to Example 17 of an embodiment of the present technology.

FIG. 43 is a flowchart for explaining an example of a method for manufacturing the surface emitting element of FIG. 42.

FIGS. 44A and 44B are cross-sectional views for each step of the method for manufacturing the surface emitting element in FIG. 42.

FIGS. 45A and 45B are cross-sectional views for each step of the method for manufacturing the surface emitting element in FIG. 42.

FIGS. 46A and 46B are cross-sectional views for each step of the method for manufacturing the surface emitting element in FIG. 42.

FIG. 47 is a cross-sectional view of a surface emitting element according to Example 18 of an embodiment of the present technology.

FIG. 48 is a diagram illustrating variations of the protruding convex surface structure.

FIG. 49 is a cross-sectional view of a surface emitting element according to Modification 1 of Example 1 of an embodiment of the present technology.

FIG. 50 is a cross-sectional view of a surface emitting element according to Modification 2 of Example 1 of an embodiment of the present technology.

FIG. 51 is a cross-sectional view of a surface emitting element according to a modification of Example 5 of an embodiment of the present technology.

FIG. 52 is a cross-sectional view of a surface emitting element according to a modification of an embodiment of the present technology.

FIG. 53 is a diagram illustrating an application example of the surface emitting element according to the present technology to a distance measurement device.

FIG. 54 is a block diagram illustrating an example of a schematic configuration of a vehicle control system.

FIG. 55 is an explanatory diagram illustrating an example of installation positions of distance measurement devices.

### MODE FOR CARRYING OUT THE INVENTION

Hereinafter, preferred embodiments of the present technology will be described in detail with reference to the accompanying drawings. Note that, in the present specification and the drawings, components having substantially the same functional configurations are denoted by the same reference signs, and redundant descriptions are omitted. The embodiments to be described below provide representative embodiments of the present technology, and the scope of the present technology is not to be narrowly interpreted according to those embodiments. In the present specification, even in a case where it is described that the surface emitting element and the individual authentication device according to the present technology exhibit a plurality of effects, the surface emitting element and the individual authentication device according to the present technology are only required to exhibit at least one effect. The effects described in the present specification are merely examples and are not limited, and other effects may be exerted.

Furthermore, the description will be given in the following order.
0. Introduction
1. Surface Emitting Element According to Example 1 of Embodiment of Present Technology
2. Surface Emitting Element According to Example 2 of Embodiment of Present Technology
3. Surface Emitting Element According to Example 3 of Embodiment of Present Technology
4. Surface Emitting Element According to Example 4 of Embodiment of Present Technology
5. Surface Emitting Element According to Example 5 of Embodiment of Present Technology
6. Surface Emitting Element According to Example 6 of Embodiment of Present Technology
7. Surface Emitting Element According to Example 7 of Embodiment of Present Technology
8. Surface Emitting Element According to Example 8 of Embodiment of Present Technology
9. Surface Emitting Element According to Example 9 of Embodiment of Present Technology
10. Surface Emitting Element According to Example 10 of Embodiment of Present Technology
11. Surface Emitting Element According to Example 11 of Embodiment of Present Technology
12. Surface Emitting Element According to Example 12 of Embodiment of Present Technology
13. Surface Emitting Element According to Example 13 of Embodiment of Present Technology
14. Surface Emitting Element According to Example 14 of Embodiment of Present Technology
15. Surface Emitting Element According to Example 15 of Embodiment of Present Technology
16. Surface Emitting Element According to Example 16 of Embodiment of Present Technology
17. Surface Emitting Element According to Example 17 of Embodiment of Present Technology
18. Surface Emitting Element According to Example 18 of Embodiment of Present Technology
19. Variations of Protruding Convex Surface Structure
20. Surface Emitting Element According to Modification 1 of Example 1 of Embodiment of Present Technology
21. Surface Emitting Element According to Modification 2 of Example 1 of Embodiment of Present Technology
22. Surface Emitting Element According to Modification of Example 5 of Embodiment of Present Technology
23. Surface Emitting Element According to Modification of Embodiment of Present Technology
24. Modifications of Present Technology
25. Application Examples to Electronic Device
26. Example in Which Surface Emitting Element Is Applied to Distance Measurement Device
27. Example in Which Distance Measurement Device Is Mounted on Moving Body

### 0. Introduction

Conventionally, in a surface emitting element such as a VCSEL or an LED, a method of reducing diffraction loss by using a concave mirror as a reflector of an element portion is known (for example, see Patent Document 1). The inventors have conducted intensive studies under the inference that it should be possible to impart special characteristics to the element portion by applying some ingenuity to the concave mirror. As a result, the inventors have succeeded in giving special characteristics to the element portion by adding a special structure to the concave mirror. The surface emitting element according to the present technology is a surface emitting element including a concave mirror having this special structure, and is expected to be used in various technical fields in addition to imaging and sensing.

Hereinafter, an embodiment of the surface emitting element according to the present technology will be described in detail with some examples.

### 1. Surface Emitting Element According to Example 1 of Embodiment of Present Technology

Hereinafter, a surface emitting element according to Example 1 of an embodiment of the present technology will be described with reference to the drawings.

### <<Configuration of Surface Emitting Element>>

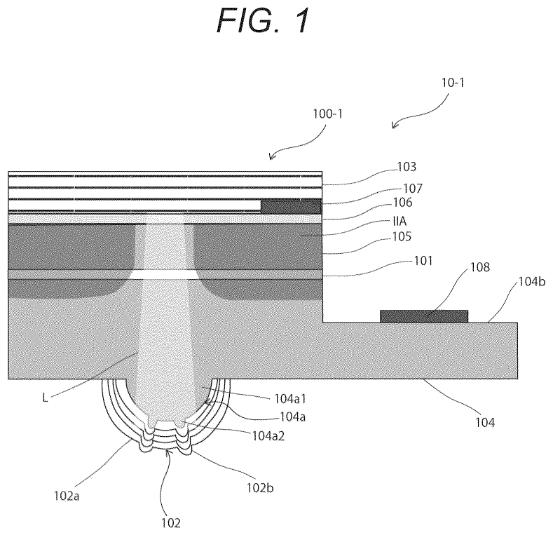

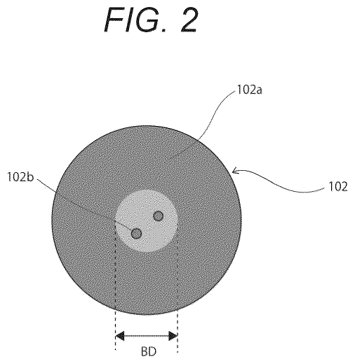

FIG. 1 is a cross-sectional view of a surface emitting element 10-1 according to Example 1 of an embodiment of the present technology. FIG. 2 is a plan view of a concave mirror 102 of the surface emitting element 10-1 according to Example 1 of an embodiment of the present technology. Hereinafter, for the sake of convenience, the upper part in the cross-sectional view of FIG. 1 and the like will be described as an upper side, and the lower part in the cross-sectional view of FIG. 1 and the like will be described as a lower side.

As will be specifically described below, the surface emitting element 10-1 is a vertical cavity surface emitting laser (VCSEL) in which a light emitting layer is sandwiched between first and second reflectors.

As an example, as illustrated in FIG. 1, the surface emitting element 10-1 includes at least one (for example, one) element portion 100-1 including a light emitting layer 101 and a concave mirror 102 disposed on one side (lower side) of the light emitting layer 101.

As an example, the element portion 100-1 further includes a reflector 103 disposed on the other side (upper side) of the light emitting layer 101. That is, the element portion 100-1 has a vertical resonator structure in which the light emitting layer 101 is disposed between the concave mirror 102 and the reflector 103.

As an example, the element portion 100-1 further includes a transparent conductive film 106 disposed between the light emitting layer 101 and the reflector 103.

As an example, the element portion 100-1 further includes a cladding layer 105 disposed between the transparent conductive film 106 and the light emitting layer 101.

In the element portion 100-1, as an example, a peripheral region of the light emitting layer 101 and the cladding layer 105 is an ion implantation region IIA. The light emitting region of the light emitting layer 101 is defined by the ion implantation region IIA.

As an example, the element portion 100-1 further includes an anode electrode 107 provided between the reflector 103 and the transparent conductive film 106 at a position not corresponding to the light emitting region.

As an example, the element portion 100-1 further includes an intermediate layer 104 disposed between the light emitting layer 101 and the concave mirror 102.

As an example, the element portion 100-1 further includes a cathode electrode 108 disposed on a cutaway electrode installation portion 104b provided in the intermediate layer 104.

### (Light Emitting Layer)

As an example, the light emitting layer 101 has a five-layered multiple quantum well structure in which an In_{0.04}Ga_{0.96}N layer (barrier layer) and an In_{0.16}Ga_{0.84}N layer (well layer) are laminated. The light emitting layer 101 is also referred to as an “active layer”.

### (Reflector)

As an example, the reflector 103 functions as a first reflector of the surface emitting element 10-1. As an example, the reflector 103 is a plane mirror. Note that, the reflector 103 may be a concave mirror. The reflector 103 is constituted by, for example, a dielectric multilayer film reflector. The dielectric multilayer film reflector includes, for example, Ta₂O₅/SiO₂, SiN/SiO₂, or the like.

### (Transparent Conductive Film)

The transparent conductive film 106 functions as a buffer layer that enhances hole injection efficiency into the light emitting layer 101 and prevents leakage. The transparent conductive film 106 is constituted by, for example, ITO, ITiO, AZO, Zno, SnO, SnO₂, SnO₃, TiO, TiO₂, graphene, or the like.

### (Cladding Layer)

The cladding layer 105 is a p-type cladding layer and is constituted by, for example, a p-GaN layer.

### (Ion Implantation Region)

The ion implantation region IIA is formed by implanting high concentration ions (for example, B⁺⁺ or the like). The ion implantation region IIA has higher resistance (carrier conductivity is low) than a region surrounded by the ion implantation region IIA, and functions as a current confinement portion. The current confinement diameter by the ion implantation region IIA can be several μm (for example, 4 μm).

### (Anode Electrode)

The anode electrode 107 is constituted by, for example, at least one metal (including an alloy) selected from the group constituted by Au, Ag, Pd, Pt, Ni, Ti, V, W, Cr, Al, Cu, Zn, Sn, and In. In a case where the anode electrode 107 has a laminated structure, the anode electrode is constituted by a material such as Ti/Au, Ti/Al, Ti/Al/Au, Ti/Pt/Au, Ni/Au, Ni/Au/Pt, Ni/Pt, Pd/Pt, or Ag/Pd. The anode electrode 107 is connected to an anode (positive electrode) of a laser driver.

### (Cathode Electrode)

The cathode electrode 108 is constituted by, for example, at least one metal (including an alloy) selected from the group constituted by Au, Ag, Pd, Pt, Ni, Ti, V, W, Cr, Al, Cu, Zn, Sn, and In. In a case where the cathode electrode 108 has a laminated structure, the cathode electrode is constituted by a material such as Ti/Au, Ti/Al, Ti/Al/Au, Ti/Pt/Au, Ni/Au, Ni/Au/Pt, Ni/Pt, Pd/Pt, or Ag/Pd. The cathode electrode 108 is electrically connected to a cathode (negative electrode) of the laser driver.

### (Intermediate Layer)

The intermediate layer 104 is configured as a single layer as an example, but may be configured as a plurality of layers. The intermediate layer 104 is an n-type cladding layer and is constituted by, for example, an n-GaN substrate. The intermediate layer 104 has a protruding convex surface structure 104a (convex surface structure) corresponding to the concave mirror 102 on the surface (surface on the lower side) on the side of the concave mirror 102.

The protruding convex surface structure 104a includes a convex surface structure 104al protruding from the back surface (lower surface) of the intermediate layer 104 to the opposite side (lower side) to the light emitting layer 101 side, and at least one (for example, two) protrusion 104a2 provided on the surface of the convex surface structure 104al.

The convex surface structure 104al has, for example, a substantially hemispherical shape, and at least a top portion (lower end portion) is located on an optical path of light L (light emitted from the light emitting layer 101 and light via the light emitting layer 101) from the light emitting layer 101. In the convex surface structure 104al, at least the surface of the top portion is constituted by a curved surface (for example, a spherical surface, a paraboloid surface, or the like). Note that, in the convex surface structure 104al, the surface of a portion other than the top portion may be configured as a flat surface. The curvature radius of the surface of the top portion of the convex surface structure 104al is preferably equal to or greater than the resonator length of the surface emitting element 10-1.

The diameter of the protrusion 104a2 is preferably 0.1 μm or more and ½ or less of the diameter of the convex surface structure 104a1. The height of the protrusion 104a2 is preferably 10 nm or more. As a scale ratio between the convex surface structure 104al and the protrusion 104a2, for example, in a case where the diameter of the convex surface structure 104al is 25 μm and the height is 1.3 μm, the diameter of the protrusion 104a2 may be 0.3 μm and the height may be 60 nm.

The protrusion 104a2 is located on the optical path of the light L from the light emitting layer 101. For example, in a case where the resonator length of the surface emitting element 10-1 is 25 μm and the curvature radius of the convex surface structure 104al is 60 μm, the beam waist is 2.6 μm, and the protrusion 104a2 is located at a position 0.5 μm away from the optical axis of the convex surface structure 104al (a position within the beam diameter BD of the light L). The diameter of the protrusion 104a2 can be, for example, 0.3 μm.

The shape of the protrusion 104a2 may be, for example, a cylinder, a cone, a truncated cone, a polygonal prism, a polygonal pyramid, a polygonal truncated cone, or any other shape.

The surface of the protrusion 104a2 preferably has a curvature. Since the surface of the protrusion 104a2 has a curvature, a special structure 102b of the concave mirror 102, which will be described later, can have a curvature.

As an example, the convex surface structure 104al (a portion corresponding to a concave mirror body 102a to be described later) of the protruding convex surface structure 104a and the protrusion 104a2 (a portion corresponding to the special structure 102b to be described later) of the protruding convex surface structure 104a are integrated. That is, the convex surface structure 104al and the protrusion 104a2 are constituted by a series of the same material.

A plurality of (for example, two) protrusions 104a2 is disposed in the in-plane direction of the convex surface structure 104a1. Here, protrusions 104a2 are disposed on both sides sandwiching the optical axis of concave mirror body 102a, but may be disposed only on one side of the optical axis.

### (Concave Mirror)

As an example, the concave mirror 102 functions as the second reflector of the surface emitting element 10-1. By using a concave mirror having positive power as the second reflector, even if the resonator length is increased (for example, even if the intermediate layer 104 is thickened), the light L from the light emitting layer 101 can be reflected and condensed on the light emitting layer 101, and a gain necessary for laser oscillation can be obtained by the light amplifying action of the light emitting layer 101. As the thickness of the intermediate layer 104 increases, the heat dissipation property at the time of manufacturing and driving the surface emitting element 10-1 is improved, and furthermore, the yield and the reliability can be improved.

As an example, the reflectance of the concave mirror 102 is set to be slightly higher than the reflectance of the reflector 103. That is, the reflector 103 is a reflector on the emission side. Note that the reflectance of the concave mirror 102 may be slightly higher than the reflectance of the reflector 103, and the concave mirror 102 may be used as a reflector on the emission side.

The concave mirror 102 is provided along the protruding convex surface structure 104a. That is, the concave mirror 102 has a shape following the protruding convex surface structure 104a.

The concave mirror 102 has a concave mirror body 102a and a special structure 102b (structure) including a protrusion or a recess. Here, the special structure 102b is provided in the concave mirror body 102a. As an example, the special structure 102b is integrated with the concave mirror body 102a. The special structure 102b can be regarded as a protrusion or a recess depending on which of one side and the other side in the thickness direction of the concave mirror body 102a is viewed from.

As an example, the concave mirror 102 (the concave mirror body 102a and the special structure 102b) includes a dielectric multilayer film reflector. The dielectric multilayer film reflector is constituted by, for example, Ta₂O₅/SiO₂, SiO₂/SiN, SiO₂/Nb₂O₅, or the like.

The concave mirror body 102a has, for example, a substantially spherical shell shape, and at least a top portion (lower end portion) is located on an optical path of the light L from the light emitting layer 101. In the concave mirror body 102a, at least the surface of the top portion is constituted by a curved surface (for example, a spherical surface, a paraboloid surface, or the like). Note that a surface of a portion other than the top portion of the concave mirror body 102a may be constituted by a flat surface.

The special structure 102b is smaller than the concave mirror body 102a (see FIGS. 1 and 2). Specifically, the diameter of the special structure 102b is preferably 0.1 μm or more and ½ or less of the diameter of the concave mirror body 102a. The height of the special structure 102b is preferably 10 nm or more. In a case where the special structure 102b is fine as described above, it can also be referred to as a “fine structure”. As a scale ratio between the concave mirror body 102a and the special structure 102b, for example, in a case where the diameter of the concave mirror body 102a is 25 μm and the height is 1.3 μm, the diameter of the special structure 102b may be 0.3 μm and the height may be 60 nm. The curvature radius of the surface of the top portion of the concave mirror body 102a is preferably equal to or greater than the resonator length of the surface emitting element 10-1. Here, as an example, the thickness of the intermediate layer 104 and/or the curvature radius of the surface of the top portion of the concave mirror body 102a (power of the top portion of the concave mirror body 102a) are set such that a condensing position (beam waist position) of light reflected by the concave mirror body 102a is located on the light emitting layer 101 or on the reflector 103 side (upper side) of the light emitting layer 101.

The special structure 102b is located on the optical path of the light L from the light emitting layer 101. For example, in a case where the resonator length of the surface emitting element 10-1 is 25 μm and the curvature radius of the concave mirror body 102a is 60 μm, the beam waist is 2.6 μm, and the special structure 102b is located at a position 0.5 μm away from the optical axis of the concave mirror body 102a (a position within the beam diameter BD of the light L) (see FIG. 2).

The special structure 102b is disposed on the optical path of the light L, thereby exerting a special optical effect (for example, reflection, refraction, diffraction, and the like) different from that of the concave mirror body 102a on the light L. In a case where the special structure 102b exerts an optical effect on the light L in this manner, it can also be referred to as an “optical structure”.

The special structure 102b preferably has curvature, that is, optical power. In this case, the special structure 102b functions as a microlens, a micromirror, or the like, and at least a part of the emitted light of the surface emitting element 10-1 can have special characteristics such as focusing, parallelism, and divergence.

The special structure 102b is provided on each dielectric film constituting the concave mirror 102. That is, the special structure 102b is provided at least on a surface farthest from the light emitting layer 101 and a surface closest to the light emitting layer 101 of the concave mirror 102. A plurality of special structures 102b is arranged side by side in the thickness direction at positions corresponding to protrusions 104a2 of the concave mirror body 102a.

A plurality of (for example, two) special structures 102b is disposed in the in-plane direction of the concave mirror body 102a. Here, the special structure 102b is disposed on both sides sandwiching the optical axis of the concave mirror body 102a, but may be disposed only on one side of the optical axis.

### <<Operation of Surface Emitting Element>>

Hereinafter, an operation of the surface emitting element 10-1 will be described.

In the surface emitting element 10-1, when a driving voltage is applied between the anode electrode 107 and the cathode electrode 108 by the laser driver, a current flowing from the anode side of the laser driver through the anode electrode 107 is injected into the light emitting layer 101 through the transparent conductive film 106 while being narrowed in the ion implantation region IIA. At this time, the light emitting layer 101 emits light, and the light L reciprocates (at this time, the light is reflected while being condensed in the vicinity of the light emitting layer 101 by the concave mirror 102, and is reflected toward the light emitting layer 101 as parallel light or weak diffusion light by the reflector 103) between the concave mirror 102 and the reflector 103 while being amplified by the light emitting layer 101, and is emitted from the reflector 103 as laser light when an oscillation condition is satisfied. At this time, since the special structure 102b has unique optical power different from that of the concave mirror body 102a, the horizontal mode is likely to be the multi-mode, and a plurality of beams is emitted from the surface emitting element 10-1. The current injected into the light emitting layer 101 flows out from the cathode electrode 108 to the cathode side of the laser driver via the intermediate layer 104. Note that, for example, even in a case where the surface emitting element 10-1 is continuously driven for a long time, the temperature rise of the element can be suppressed by the heat dissipation function of the intermediate layer 104, and a stable operation can be performed.

### <<Method for Manufacturing Surface Emitting Element>>

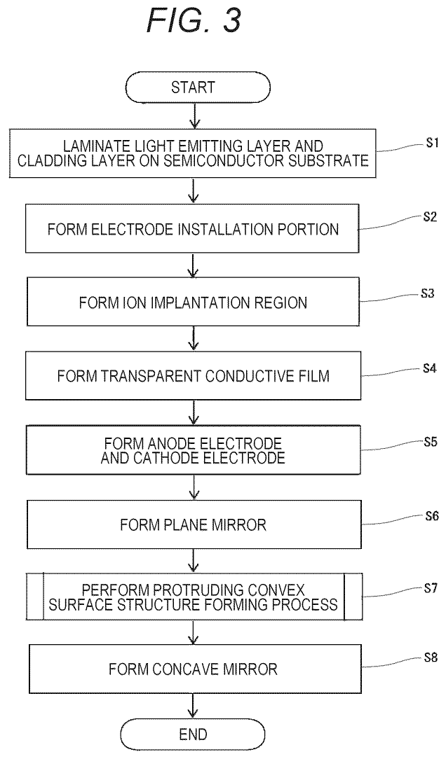

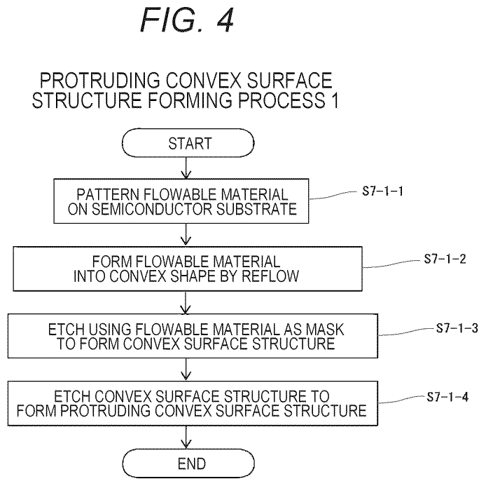

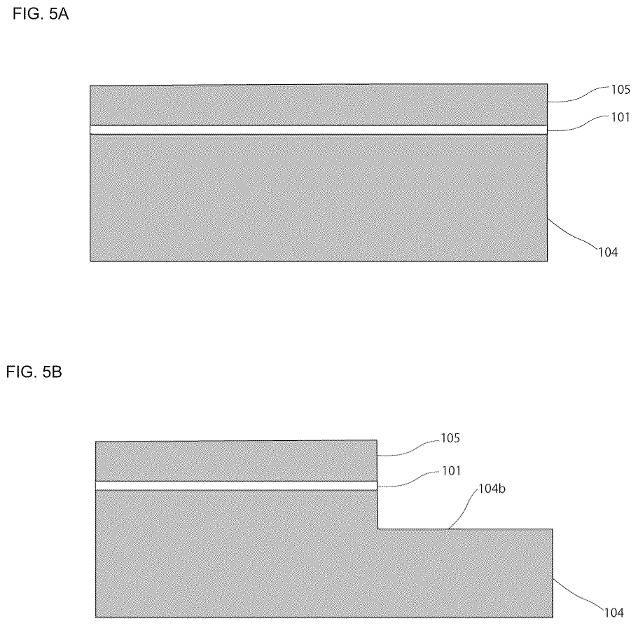

Hereinafter, a method for manufacturing the surface emitting element 10-1 will be described with reference to the flowcharts of FIGS. 3 and 4 and the cross-sectional views of FIGS. 5A to 9B. Here, as an example, a plurality of surface emitting elements 10-1 is simultaneously generated on one wafer (semiconductor substrate (for example, n-GaN substrate)) as a base material of the intermediate layer 104. Subsequently, the plurality of continuous integrated surface emitting elements 10-1 is separated from each other to obtain chip-shaped surface emitting elements (surface emitting element chips).

### (Step S1)

In step S1, the light emitting layer 101 and the cladding layer 105 are laminated on the semiconductor substrate (see FIG. 5A). Specifically, the light emitting layer 101 and the cladding layer 105 are laminated in this order on the semiconductor substrate to be the intermediate layer 104 in the growth chamber by a metal organic chemical vapor deposition method (MOCVD method) or a molecular beam epitaxy method (MBE method) to generate a laminate.

### (Step S2)

In step S2, the electrode installation portion 104b is formed (see FIG. 5B). Specifically, a resist pattern covering a position other than the position where the electrode installation portion 104b is formed on the laminate is formed, and the laminate is etched using the resist pattern as a mask. At this time, etching is performed until the semiconductor substrate to be the intermediate layer 104 is exposed. As a result, the cutaway electrode installation portion 104b is formed in the laminate.

### (Step S3)

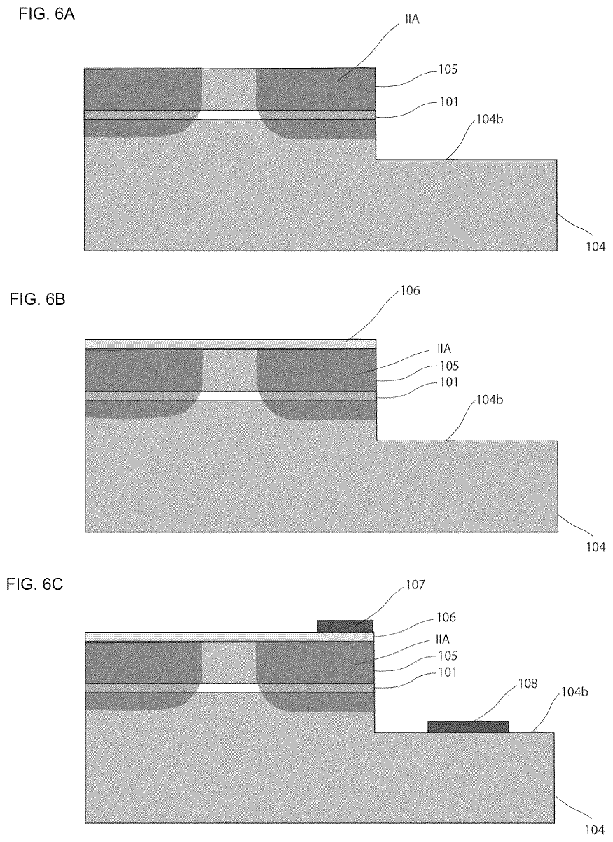

In step S3, the ion implantation region IIA is formed (see FIG. 6A). Specifically, a protective film constituted by resist, SiO₂, or the like is formed to cover a portion other than the position where the ion implantation region IIA is formed on the laminate, and ions (for example, B++) are implanted into the laminate from the cladding layer 105 side using the protective film as a mask. At this time, the implantation depth of the ion implantation is assumed to reach the intermediate layer 104.

### (Step S4)

In step S4, the transparent conductive film 106 is formed (see FIG. 6B). Specifically, the transparent conductive film 106 is formed on the cladding layer 105 by, for example, a vacuum vapor deposition method, sputtering, or the like.

### (Step S5)

In step S5, the anode electrode 107 and the cathode electrode 108 are formed (see FIG. 6C). Specifically, for example, a lift-off method is used to form the anode electrode 107 on the transparent conductive film 106, and form the cathode electrode 108 on the electrode installation portion 104b.

### (Step S6)

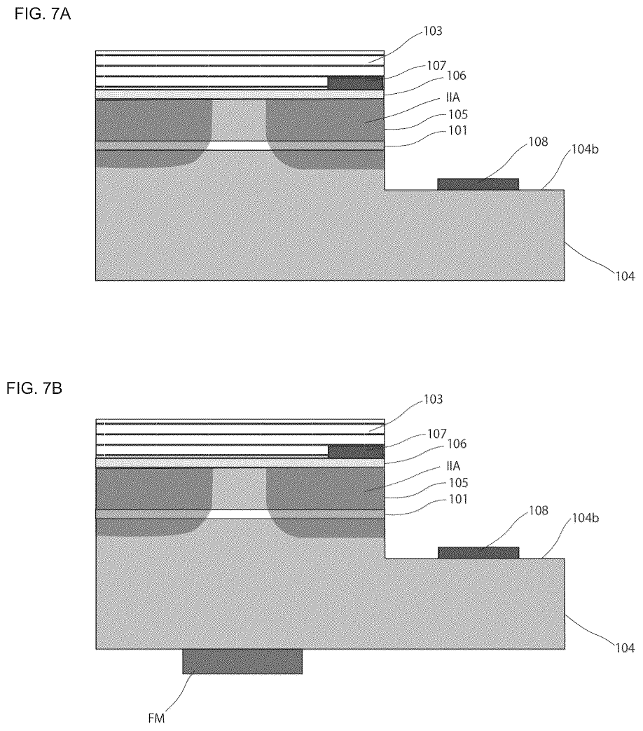

In step S6, a plane mirror as the reflector 103 is formed (see FIG. 7A). Specifically, a dielectric multilayer film to be the reflector 103 (for example, plane mirror) is formed on the transparent conductive film 106 by, for example, a vacuum vapor deposition method, a sputtering method, a CVD method, or the like.

### (Step S7: Protruding Convex Surface Structure Forming Process 1)

In step S7 (steps S7-1-1 to S7-1-4), a protruding convex surface structure forming process 1 (see FIG. 4) which is an example of the protruding convex surface structure forming process is performed.

In step S7-1-1, the flowable material FM is patterned on the semiconductor substrate to be the intermediate layer 104 (see FIG. 7B). Specifically, the flowable material FM (for example, photoresist) is formed by photolithography at a position where the protruding convex surface structure 104a on the back surface of the semiconductor substrate is to be formed.

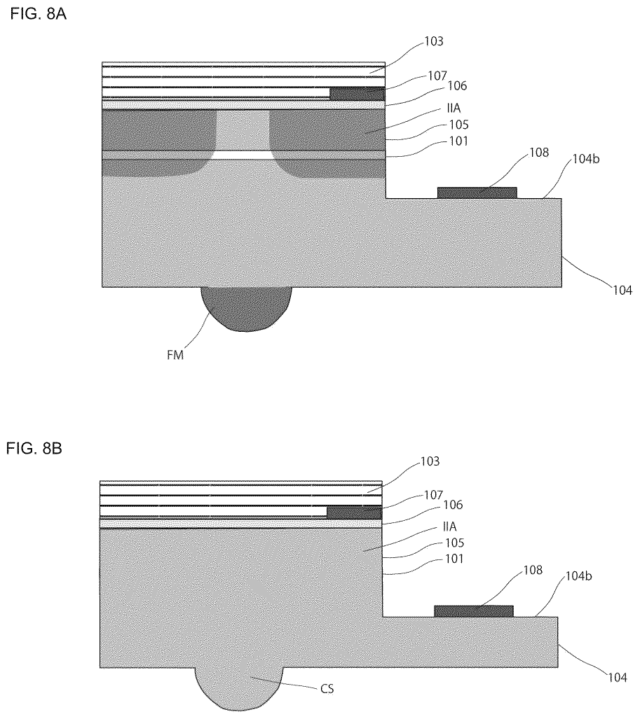

In step S7-1-2, the flowable material FM is formed into a convex shape by reflow (see FIG. 8A). Specifically, the flowable material FM is molded into a convex shape (for example, a substantially hemispherical shape) by reflow at a temperature of 200° C.

In step S7-1-3, etching is performed using the flowable material FM as a mask to form the convex surface structure CS (see FIG. 8B). Specifically, the intermediate layer 104 is, for example, dry-etched by photolithography using the flowable material FM as a mask to form the convex surface structure CS (for example, a substantially hemispherical structure).

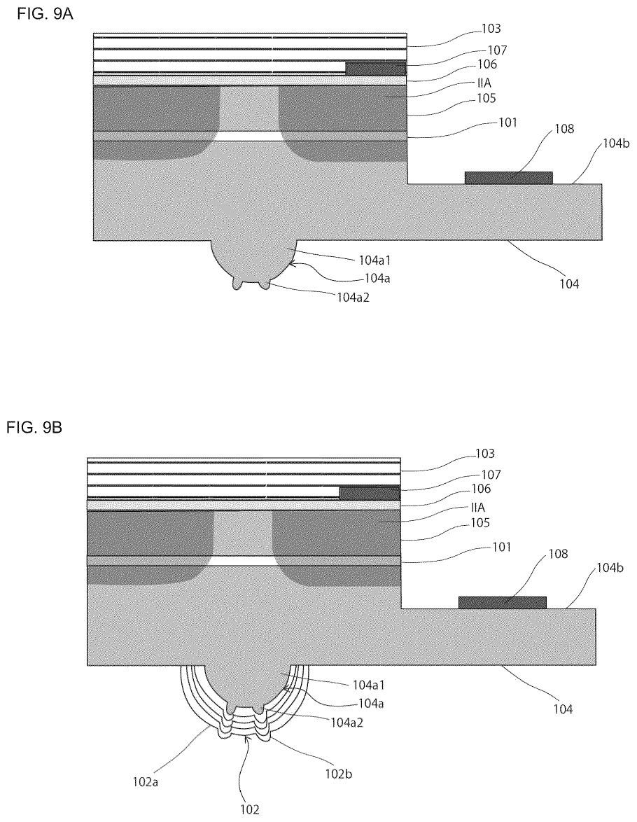

In step S7-1-4, the convex surface structure CS is etched to form the protruding convex surface structure 104a (see FIG. 9A). Specifically, first, a resist pattern covering a portion other than the position where the protrusion 104a2 of the convex surface structure CS is formed is formed, and the convex surface structure CS is etched (for example, dry etching) by the height of the protrusion 104a2 using the resist pattern as a mask to form the protrusion 104a2 on the convex surface structure 104al.

Note that the protruding convex surface structure 104a can also be formed by mechanically polishing the convex surface structure CS.

### (Step S8)

In step S8, the concave mirror 102 is formed (see FIG. 9B). Specifically, the material of the concave mirror 102 (for example, a dielectric multilayer film) is formed on the protruding convex surface structure 104a by, for example, a vacuum vapor deposition method, a sputtering method, a CVD method, or the like. As a result, the concave mirror 102 having a shape following the protruding convex surface structure 104a is formed. As a result, a plurality of surface emitting elements 10-1 is generated on a wafer (semiconductor substrate (for example, n-GaN substrate)). Thereafter, the plurality of continuous integrated surface emitting elements 10-1 is separated by dicing to obtain chip-shaped surface emitting elements 10-1 (surface emitting element chips). Thereafter, the surface emitting element 10-1 is mounted on, for example, a CAN package. More specifically, the surface of the surface emitting element 10-1 on the concave mirror 102 side is soldered to the CAN package.

### <<Effects of Surface Emitting Element>>

Hereinafter, effects of the surface emitting element 10-1 according to Example 1 of an embodiment of the present technology will be described.

A surface emitting element 10-1 according to Example 1 of an embodiment of the present technology includes at least one element portion 100-1 including a light emitting layer 101 and a concave mirror 102 disposed on one side of the light emitting layer 101, and the concave mirror 102 includes a concave mirror body 102a and a special structure 102b including a protrusion or a recess.

In this case, since the concave mirror 102 has the special structure 102b, the element portion 100-1 can have special characteristics.

For example, by providing the special structure 102b, the horizontal mode is likely to be the multi-mode, and a plurality of beams can be emitted from the surface emitting element 10-1. As a result, it is possible to increase the output and to suppress speckle noise. For example, by providing the special structure 102b on the outermost surface of the concave mirror 102, wettability between the outermost surface of the concave mirror 102 and solder is improved when the surface emitting element 10-1 is mounted in a CAN package. As a result, the adhesion between the surface emitting element 10-1 and the CAN package can be improved, and the bonding failure can be suppressed, or the yield is improved.

The element portion 100-1 further includes a reflector 103 disposed on the other side of the light emitting layer 101. Thus, the surface emitting element 10-1 can constitute a surface emitting laser.

The special structure 102b is smaller than the concave mirror body 102a. This allows the element portion 100-1 to have special characteristics while taking advantage of the function of the concave mirror body 102a.

The special structure 102b has a curvature. As a result, the special structure 102b can function as a microlens, a micromirror, or the like.

The special structure 102b is provided at least on the surface of the concave mirror 102 farthest from the light emitting layer 101. Thus, for example, the adhesion to the CAN package can be reliably improved.

The special structure 102b is provided at least on a surface of the concave mirror 102 closest to the light emitting layer 101. As a result, an anchor effect (mechanical coupling effect, anchoring effect, and fastener effect) can be obtained between the concave mirror 102 and the protruding convex surface structure 104a.

A plurality of special structures 102b is disposed in the in-plane direction of the concave mirror body 102a. As a result, a plurality of positions in the in-plane direction of the concave mirror body 102a can have special characteristics.

The concave mirror body 102a and the special structure 102b are integrated. As a result, for example, the concave mirror 102 can be constituted only by the material of the concave mirror body 102a.

The element portion 100-1 further includes an intermediate layer 104 disposed between the concave mirror 102 and the light emitting layer 101, and the intermediate layer 104 has a protruding convex surface structure 104a corresponding to the concave mirror 102 on a surface on the concave mirror 102 side. As a result, since the protruding convex surface structure 104a serves as a base, the shape stability of the concave mirror 102 including the special structure 102b is improved.

A convex surface structure 104al which is a portion corresponding to the concave mirror body 102a of the protruding convex surface structure 104a and a protrusion 104a2 which is a portion corresponding to the special structure 102b of the protruding convex surface structure 104a are integrated. As a result, the entire protruding convex surface structure 104a can be constituted by the same material.

The special structure 102b is disposed at a position on the optical path of the light L from the light emitting layer 101. Thus, a special optical effect can be imparted to the light L from the light emitting layer 101.

A plurality of special structures 102b is disposed in the thickness direction of the concave mirror body 102a. As a result, a special optical effect can be stably imparted to the light L by the multiplexed special structure 102b.

### 2. Surface Emitting Element According to Example 2 of Embodiment of Present Technology

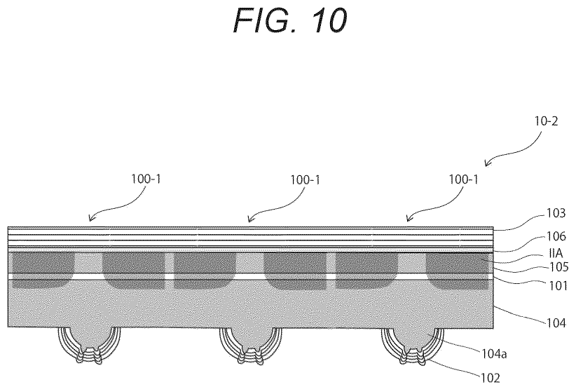

Hereinafter, a surface emitting element according to Example 2 of an embodiment of the present technology will be described with reference to the drawings. FIG. 10 is a cross-sectional view of a surface emitting element 10-2 according to Example 2 of an embodiment of the present technology.

As illustrated in FIG. 10, the surface emitting element 10-2 is a surface emitting laser array in which a plurality of element portions 100-1 of the surface emitting element 10-1 according to Example 1 is arranged in an array.

As an example, the pitch (center interval) of the plurality of element portions 100-1 in the surface emitting element 10-2 is several tens of μm (for example, 25 μm). The plurality of element portions 100-1 may be arranged in a hexagonal close-packed array. For example, in the surface emitting element 10-2, the convex surface structure 104al may have a curvature radius of 32 μm and a resonator length of 25 μm.

In the surface emitting element 10-2, the plane orientation of the substrate as the intermediate layer 104 is not particularly limited, but for example, m75 plane GaN or the like can be used. The oscillation wavelength of the surface emitting element 10-2 is, for example, 450 nm.

As an example, the surface emitting element 10-2 can be manufactured by simultaneously generating a plurality of surface emitting laser arrays in which a plurality of element portions 100-1 is two-dimensionally arranged on one wafer (for example, an n-GaN substrate) serving as a base material of the intermediate layer 104, and separating a plurality of continuous integrated surface emitting laser arrays by dicing to form a plurality of chip-shaped surface emitting laser arrays.

According to the surface emitting element 10-2, it is possible to realize a surface emitting laser array in which a plurality of element portions 100-1 having special characteristics is arranged in an array.

Note that, although illustration of the anode electrode 107 and the cathode electrode 108 is omitted in FIG. 10, the anode electrode 107 and the cathode electrode 108 may be provided in common in the plurality of element portions 100-1 and may be collectively driven, or the anode electrode 107 and/or the cathode electrode 108 may be provided for each element portion 100-1 and each element portion 100-1 may be independently driven.

### 3. Surface Emitting Element According to Example 3 of Embodiment of Present Technology

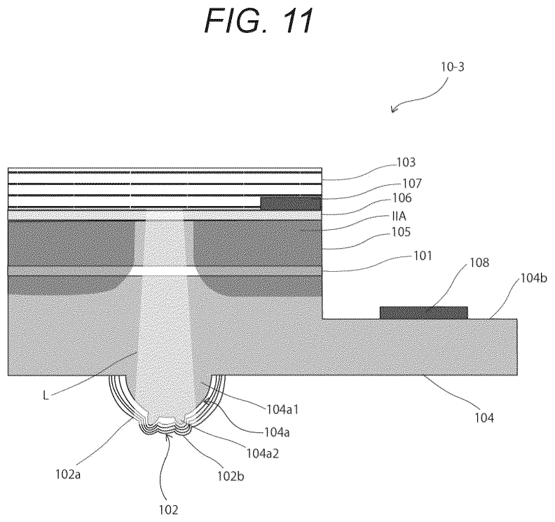

Hereinafter, a surface emitting element according to Example 3 of an embodiment of the present technology will be described with reference to the drawings. FIG. 11 is a cross-sectional view of a surface emitting element 10-3 according to Example 3 of an embodiment of the present technology.

The surface emitting element 10-3 has a configuration similar to the surface emitting element 10-1 according to Example 1 in the element portion 100-3 except that the height of the special structure 102b of the concave mirror 102 is lower than the height of the protrusion 104a2 of the protruding convex surface structure 104a as illustrated in FIG. 11.

In the surface emitting element 10-3, as an example, the height of the protrusion 104a2 is 80 nm, and the height of the special structure 102b on the outermost surface of the concave mirror 102 is 30 nm.

The surface emitting element 10-3 performs an operation similar to the surface emitting element 10-1 according to Example 1, and can be manufactured by a similar manufacturing method.

According to the surface emitting element 10-3, an effect similar to that of the surface emitting element 10-1 according to Example 1 can be obtained.

### 4. Surface Emitting Element According to Example 4 of Embodiment of Present Technology

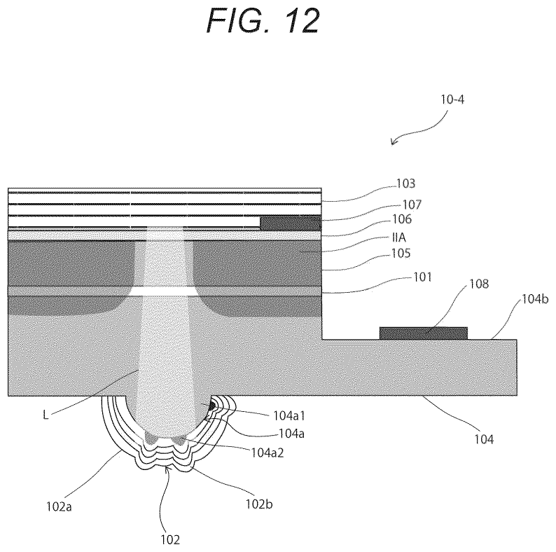

Hereinafter, a surface emitting element according to Example 4 of an embodiment of the present technology will be described with reference to the drawings. FIG. 12 is a cross-sectional view of a surface emitting element 10-4 according to Example 4 of an embodiment of the present technology.

### <<Configuration of Surface Emitting Element>>

As illustrated in FIG. 12, the surface emitting element 10-4 has a configuration similar to the surface emitting element 10-1 according to Example 1 except that, in the element portion 100-4, a convex surface structure 104al which is a portion corresponding to the concave mirror body 102a of the protruding convex surface structure 104a and a protrusion 104a2 which is a portion corresponding to the special structure 102b of the protruding convex surface structure 104a are separated from each other, and the number of the special structure 102b and the protrusion 104a2 is large.

The surface emitting element 10-4 also performs an operation similar to the surface emitting element 10-1 and exhibits a similar effect.

### <<Method for Manufacturing Surface Emitting Element>>

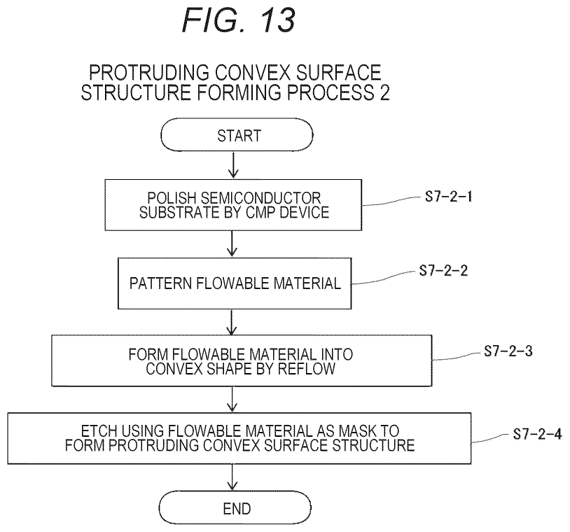

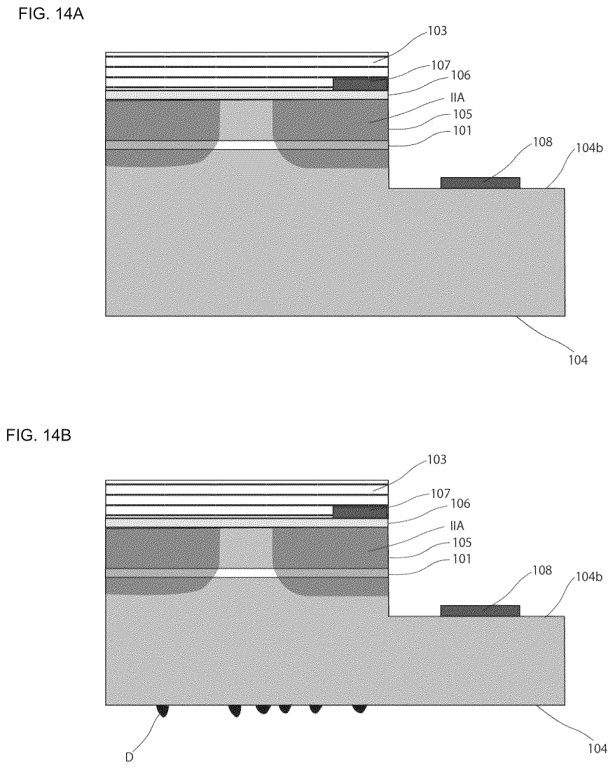

The surface emitting element 10-4 can be manufactured by a procedure (in steps S1 to S8, but in step S7, the protruding convex surface structure forming process 2 is performed) substantially similar to the method for manufacturing the surface emitting element 10-1 illustrated in the flowchart of FIG. 3. Hereinafter, the protruding convex surface structure forming process 2 will be described with reference to the flowchart of FIG. 13 and the cross-sectional views of FIGS. 14A to 16B.

### (Protruding Convex Surface Structure Forming Process 2)

In step S7-2-1, the back surface of the semiconductor substrate (see, for example, n-GaN substrate, FIG. 14A) to be the intermediate layer 104 is polished by a chemical mechanical polisher (CMP) device to thin the semiconductor substrate, and an organic substance or an inorganic substance (for example, silica) contained in the polishing liquid is attached as an attached substance to the back surface of the semiconductor substrate (see FIG. 14B).

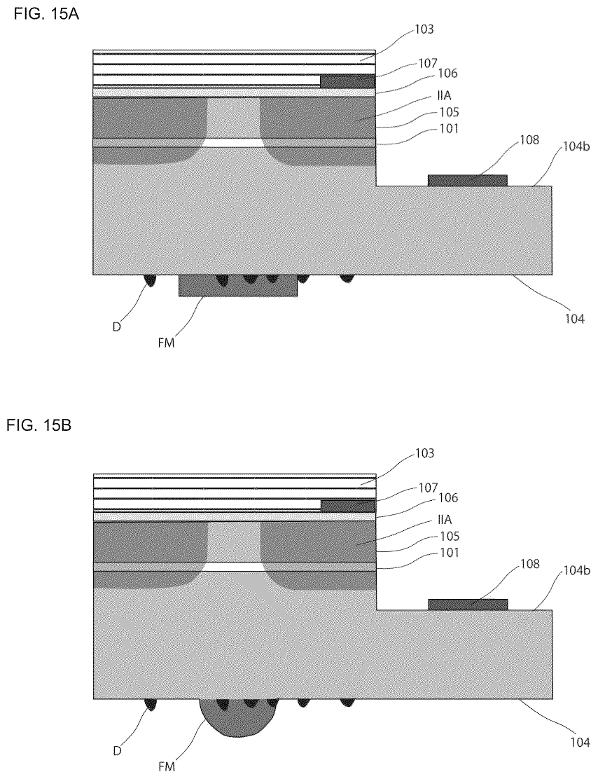

In step S7-2-2, the flowable material FM is patterned. Specifically, a photoresist as the flowable material FM is patterned by an aligner (exposure device) (see FIG. 15A).

In step S7-2-3, the flowable material FM is formed into a convex shape by reflow. Specifically, the flowable material FM is molded into a substantially hemispherical convex shape by reflow (temperature: 200° C.) (see FIG. 15B).

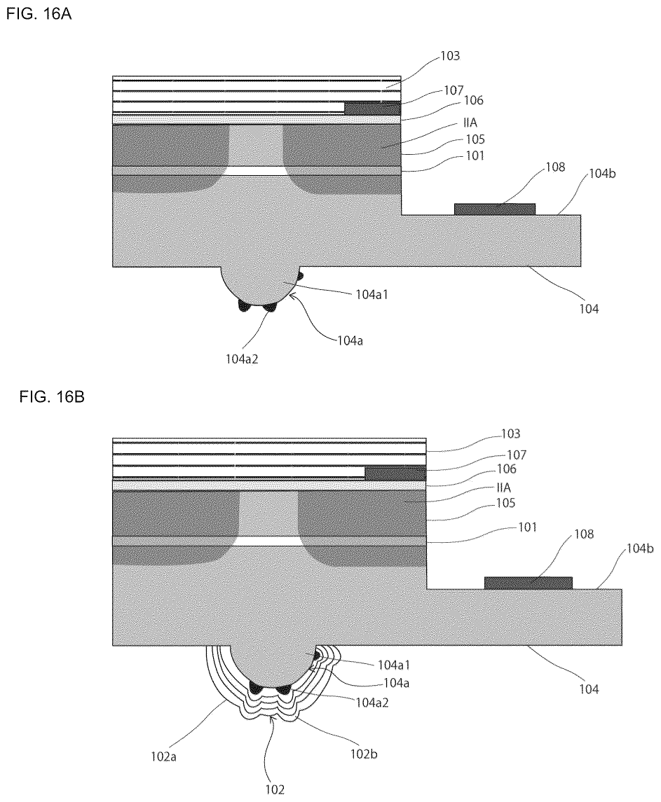

In step S7-2-4, etching is performed using the flowable material FM as a mask to form the protruding convex surface structure 104a. Specifically, the substrate as the intermediate layer 104 is etched (for example, dry etching) using the flowable material FM as a mask to form the protruding convex surface structure 104a in which the attached substance protrudes as the protrusion 104a2 from the surface of the convex surface structure 104al (see FIG. 16A).

After the protruding convex surface structure forming process 2 is performed, in step S8, the concave mirror 102 is formed for the protruding convex surface structure 104a (see FIG. 16B).

In step S7 of FIG. 3, the surface emitting element 10-4 can be manufactured by performing a protruding convex surface structure forming process 3 to 5 described below instead of the protruding convex surface structure forming process 2.

### (Protruding Convex Surface Structure Forming Process 3)

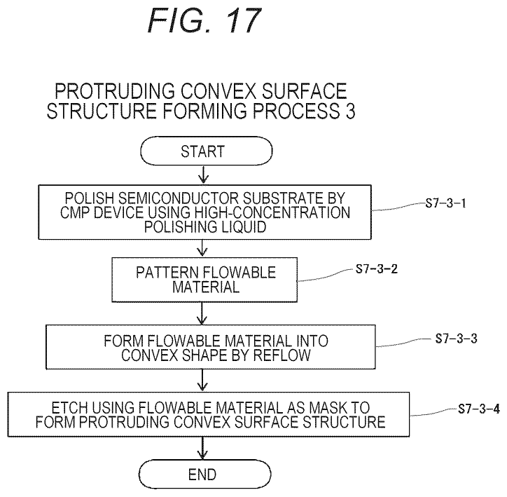

As illustrated in the flowchart of FIG. 17 (steps S7-3-1 to 7-3-4), the protruding convex surface structure forming process 3 is performed in a procedure similar to the protruding convex surface structure forming process 2 illustrated in the flowchart of FIG. 13 except for the first step S7-3-1.

In step S7-3-1, the semiconductor substrate to be the intermediate layer 104 is polished by a CMP device using a high-concentration polishing liquid to thin the semiconductor substrate, and an organic substance or an inorganic substance (for example, silica) contained in the polishing liquid is attached as an attached substance to the back surface of the semiconductor substrate. In this case, a large number of attached substances can be randomly attached to the back surface of the semiconductor substrate, which is effective in a case where it is desired to increase the number of protrusions 104a2 and special structures 102b.

### (Protruding Convex Surface Structure Forming Process 4)

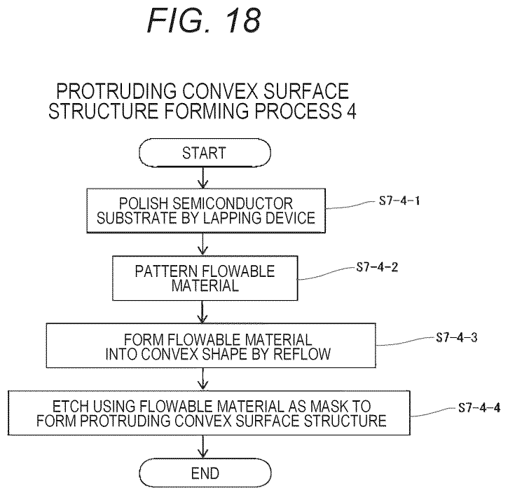

As illustrated in the flowchart of FIG. 18 (steps S7-4-1 to S7-4-4), the protruding convex surface structure forming process 4 is performed in a procedure similar to the protruding convex surface structure forming process 2 illustrated in the flowchart of FIG. 13 except for the first step S7-4-1.

In step S7-4-1, the semiconductor substrate to be the intermediate layer 104 is polished by a lapping device to thin the semiconductor substrate, and an organic substance contained in a grindstone or a grinding liquid is attached to the back surface of the semiconductor substrate as an attached substance.

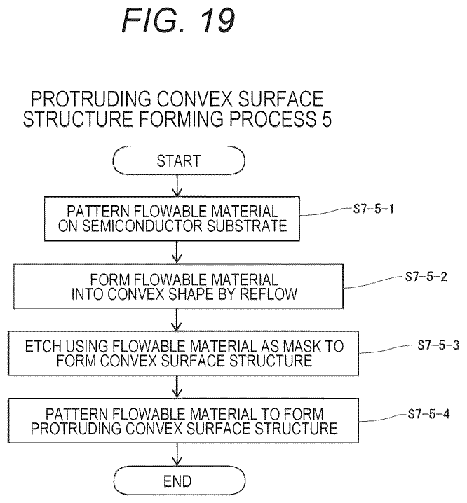

(Protruding Convex Surface Structure Forming Process 5) As illustrated in the flowchart of FIG. 19 (steps S7-5-1 to S7-5-4), the protruding convex surface structure forming process 5 is performed in a procedure similar to the protruding convex surface structure forming process 1 illustrated in the flowchart of FIG. 4 except for the last step S7-5-4.

In step S7-5-4, the flowable material is patterned to form the protruding convex surface structure 104a. Specifically, by patterning a photoresist as a flowable material on the convex surface structure 104al using an aligner, the protruding convex surface structure 104a in which the protrusion 104a2 protrudes from the convex surface structure 104al is formed.

### <<Effects of Surface Emitting Element and Manufacturing Method Thereof>>

According to the surface emitting element 10-4, effects similar to those of the surface emitting element according to Example 1 can be obtained, and since the number of the special structure 102b and the number of the protrusions 104a2 are large, the anchor effect between the protruding convex surface structure 104a and the concave mirror 102 is high, and the solder bondability in a case where the surface emitting element 10-4 is mounted on a CAN package is excellent.

According to the method for manufacturing the surface emitting element 10-4 (however, in a case where the protruding convex surface structure forming process 2 to 4 is performed), since the protrusion 104a2 is formed using the attached substance generated in the thinning step of the semiconductor substrate, thinning of the semiconductor substrate and material generation of the protrusion 104a2 can be simultaneously performed, and the manufacturing efficiency is excellent.

According to the method for manufacturing the surface emitting element 10-4 (however, in a case where the protruding convex surface structure forming process 5 is performed), the protrusion 104a2 can be accurately formed at a desired position of the convex surface structure 104al.

### 5. Surface Emitting Element According to Example 5 of Embodiment of Present Technology

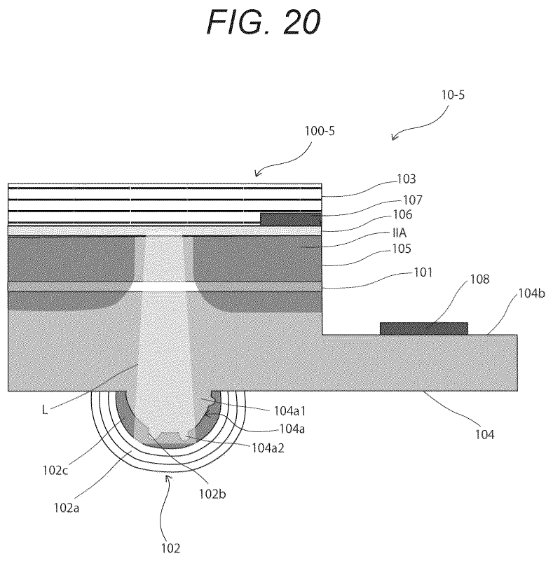

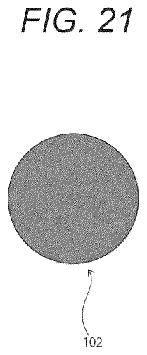

Hereinafter, a surface emitting element according to Example 5 of an embodiment of the present technology will be described with reference to the drawings. FIG. 20 is a cross-sectional view of a surface emitting element 10-5 according to Example 5 of an embodiment of the present technology. FIG. 21 is a plan view of a concave mirror 102 of the surface emitting element 10-5 according to Example 5 of an embodiment of the present technology.

As illustrated in FIGS. 20 and 21, in the element portion 100-5, the surface emitting element 10-5 has a configuration substantially similar to the surface emitting element 10-1 according to Example 1 except that the concave mirror body 102a and the special structure 102b are separate bodies, and the number of special structures and protrusions is large.

In the surface emitting element 10-5, the concave mirror 102 has an adhesive layer 102c in which a special structure 102b is provided inside between the concave mirror body 102a and the protruding convex surface structure 104a.

The surface of the adhesive layer 102c on the protruding convex surface structure 104a side has a shape following the surface of the protruding convex surface structure 104a, and is provided with a recess as the special structure 102b into which the protrusion 104a2 enters.

As a material of the adhesive layer 102c, for example, spin-on glass (SOG) or the like can be used.

The surface emitting element 10-5 performs an operation similar to the surface emitting element 10-1.

The surface emitting element 10-5 can be manufactured by a manufacturing method similar to the method for manufacturing the surface emitting element 10-1 according to Example 1 except that the adhesive layer 102c is formed on the protruding convex surface structure 104a and then the concave mirror body 102a is formed on the adhesive layer 102c.

According to the surface emitting element 10-5, it is possible to obtain an effect similar to that of the surface emitting element 10-4 according to Example 4 except that solder bondability is poor in a case where the surface emitting element 10-5 is mounted on a CAN package.

### 6. Surface Emitting Element According to Example 6 of Embodiment of Present Technology

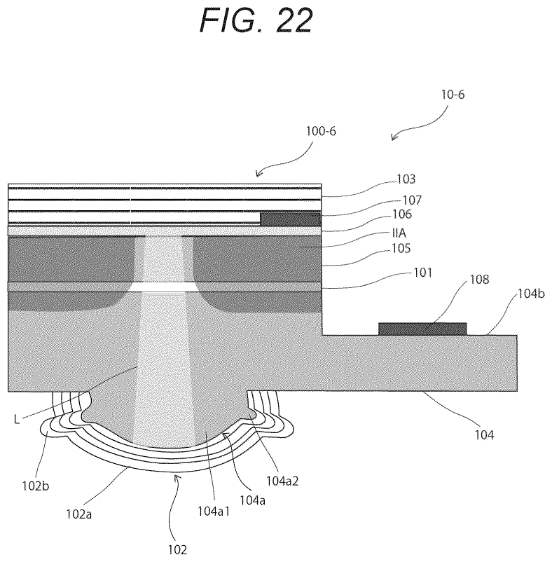

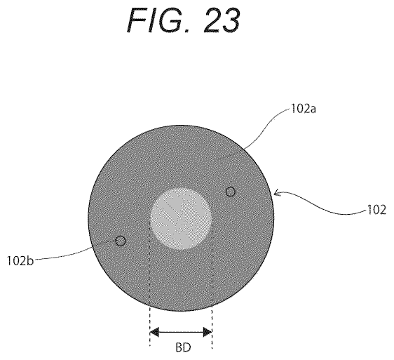

Hereinafter, a surface emitting element according to Example 6 of an embodiment of the present technology will be described with reference to the drawings. FIG. 22 is a cross-sectional view of a surface emitting element 10-6 according to Example 6 of an embodiment of the present technology. FIG. 23 is a plan view of a concave mirror 102 of the surface emitting element 10-6 according to Example 6 of an embodiment of the present technology.

In the surface emitting element 10-6, in the element portion 100-6, as illustrated in FIGS. 22 and 23, the special structure 102b is disposed at a position deviated from the optical path of the light L from the light emitting layer 101 (position outside the beam diameter BD of the light L).

That is, in the surface emitting element 10-6, the special structure 102b does not exert an optical effect on the light L, only the protrusion 104a2 contributes to an anchor effect between the concave mirror 102 and the protruding convex surface structure 104a, and the special structure 102b contributes to improvement in solder bondability between the concave mirror 102 and the CAN package.

Since only the reflection characteristic of the concave mirror body 102a of the concave mirror 102 contributes to laser oscillation, the surface emitting element 10-6 performs laser oscillation in the horizontal mode of the single mode. The surface emitting element 10-6 can be manufactured by a manufacturing method similar to the method for manufacturing the surface emitting element 10-1.

The surface emitting element 10-6 is effective particularly in a case where it is desired to use laser light in a single horizontal mode.

### 7. Surface Emitting Element According to Example 7 of Embodiment of Present Technology

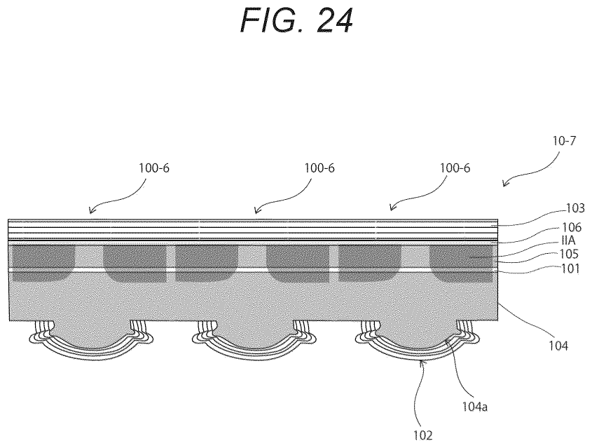

Hereinafter, a surface emitting element according to Example 7 of an embodiment of the present technology will be described with reference to the drawings. FIG. 24 is a cross-sectional view of a surface emitting element 10-7 according to Example 7 of an embodiment of the present technology.

As illustrated in FIG. 24, the surface emitting element 10-7 is a surface emitting laser array in which a plurality of element portions 100-6 of the surface emitting element 10-6 according to Example 6 is arranged in an array.

As an example, the pitch (center interval) of the plurality of element portions 100-6 in the surface emitting element 10-7 is several tens of μm (for example, 25 μm). The plurality of element portions 100-6 may be arranged in a hexagonal close-packed array. For example, in the surface emitting element 10-7, the curvature radius of the protruding convex surface structure 104a may be 32 μm, and the resonator length may be 25 μm.

In the surface emitting element 10-7, the plane orientation of the substrate as the intermediate layer 104 is not particularly limited, but for example, m75 plane GaN or the like can be used. The oscillation wavelength of the surface emitting element 10-7 is, for example, 450 nm.

As an example, the surface emitting element 10-7 can be manufactured by simultaneously generating a plurality of surface emitting laser arrays in which a plurality of element portions 100-6 is two-dimensionally arranged on one wafer (for example, an n-GaN substrate) serving as a base material of the intermediate layer 104, and separating a plurality of continuous integrated surface emitting laser arrays by dicing to form a plurality of chip-shaped surface emitting laser arrays.

According to the surface emitting element 10-7, it is possible to realize a surface emitting laser array in which a plurality of element portions 100-6 having special characteristics is arranged in an array.

Note that, although illustration of the anode electrode 107 and the cathode electrode 108 is omitted in FIG. 24, the anode electrode 107 and the cathode electrode 108 may be provided in common in the plurality of element portions 100-6 and may be collectively driven, or the anode electrode 107 and/or the cathode electrode 108 may be provided for each element portion 100-6 and each element portion 100-6 may be independently driven.

### 8. Surface Emitting Element According to Example 8 of Embodiment of Present Technology

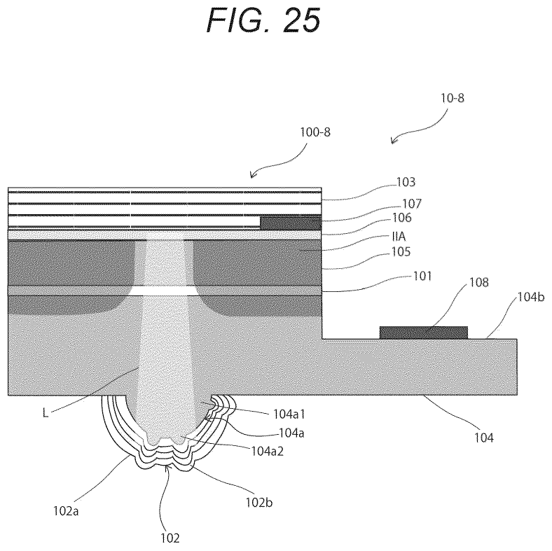

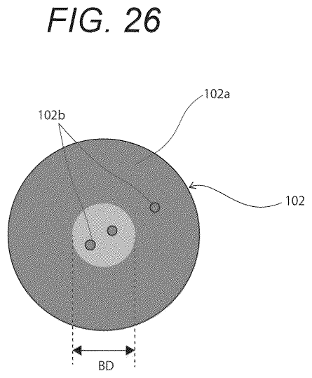

Hereinafter, a surface emitting element according to Example 8 of an embodiment of the present technology will be described with reference to the drawings. FIG. 25 is a cross-sectional view of a surface emitting element 10-8 according to Example 8 of an embodiment of the present technology. FIG. 26 is a plan view of a surface emitting element 10-8 according to Example 8 of an embodiment of the present technology.

As illustrated in FIGS. 25 and 26, the surface emitting element 10-8 has a configuration substantially similar to the surface emitting element 10-1 according to Example 1 except that the concave mirror 102 includes a special structure 102b arranged at a position on the optical path of the light L from the light emitting layer 101 and a special structure 102b arranged at a position (position outside the beam diameter BD of the light L) deviated from the optical path of the light L from the light emitting layer 101 in the element portion-100-8.

The surface emitting element 10-8 can be manufactured by a manufacturing method similar to the method for manufacturing the surface emitting element 10-1 according to Example 1.

According to the surface emitting element 10-8, an effect similar to that of the surface emitting element 10-4 according to Example 4 can be obtained.

### 9. Surface Emitting Element According to Example 9 of Embodiment of Present Technology

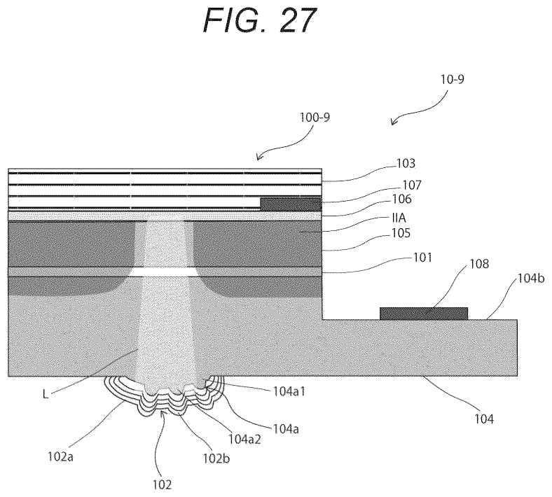

Hereinafter, a surface emitting element according to Example 9 of an embodiment of the present technology will be described with reference to the drawings. FIG. 27 is a cross-sectional view of a surface emitting element 10-9 according to Example 9 of an embodiment of the present technology.

The surface emitting element 10-9 has a configuration similar to the surface emitting element 10-1 according to Example 1 in the element portion 100-9 except that the heights of the convex surface structure 104al and the concave mirror body 102a are low and the number of the protrusions 104a2 and the special structures 102b is large as illustrated in FIG. 27.

In the surface emitting element 10-9, as an example, the convex surface structure 104al has a diameter of 25 μm, a height of 0.12 μm, a curvature radius of 650 μm, the protrusion 104a2 has a diameter of 0.3 μm, a height of 60 nm, and a current confinement diameter of 8 μm.

The surface emitting element 10-9 can be manufactured by a manufacturing method similar to the method for manufacturing the surface emitting element 10-1 according to Example 1.

According to the surface emitting element 10-9, it is possible to achieve effects similar to those of the surface emitting element 10-4 according to Example 4 and to emit a plurality of beams having a large beam diameter (large near-field pattern).

### 10. Surface Emitting Element According to Example 10 of Embodiment of Present Technology

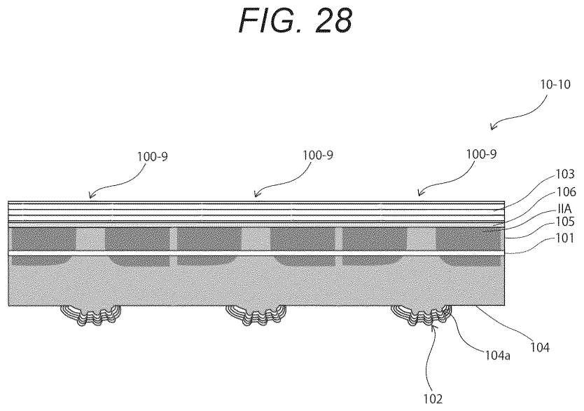

Hereinafter, a surface emitting element according to Example 10 of an embodiment of the present technology will be described with reference to the drawings. FIG. 28 is a cross-sectional view of a surface emitting element 10-10 according to Example 10 of an embodiment of the present technology.

As illustrated in FIG. 28, the surface emitting element 10-10 is a surface emitting laser array in which a plurality of element portions 100-9 of the surface emitting element 10-9 according to Example 9 is arranged in an array.

As an example, the pitch (center interval) of the plurality of element portions 100-9 in the surface emitting element 10-10 is several tens of μm (for example, 25 μm). The plurality of element portions 100-9 may be arranged in a hexagonal close-packed array.

In the surface emitting element 10-10, the plane orientation of the substrate as the intermediate layer 104 is not particularly limited, but for example, m75 plane GaN or the like can be used. The oscillation wavelength of the surface emitting element 10-10 is, for example, 450 nm.

As an example, the surface emitting element 10-10 can be manufactured by simultaneously generating a plurality of surface emitting laser arrays in which a plurality of element portions 100-9 is two-dimensionally arranged on one wafer (for example, an n-GaN substrate) serving as a base material of the intermediate layer 104, and separating a plurality of continuous integrated surface emitting laser arrays by dicing to form a plurality of chip-shaped surface emitting laser arrays.

According to the surface emitting element 10-10, it is possible to realize a surface emitting laser array in which a plurality of element portions 100-9 having special characteristics is arranged in an array.

Note that, although illustration of the anode electrode 107 and the cathode electrode 108 is omitted in FIG. 28, the anode electrode 107 and the cathode electrode 108 may be provided in common in the plurality of element portions 100-9 and may be collectively driven, or the anode electrode 107 and/or the cathode electrode 108 may be provided for each element portion 100-9 and each element portion 100-9 may be independently driven.

### 11. Surface Emitting Element According to Example 11 of Embodiment of Present Technology

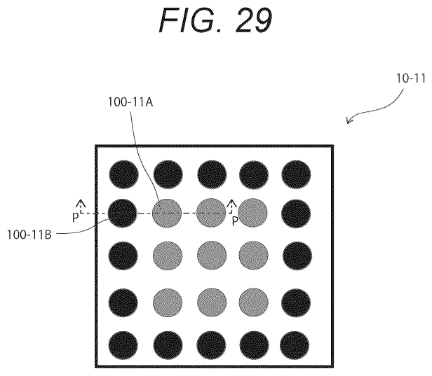

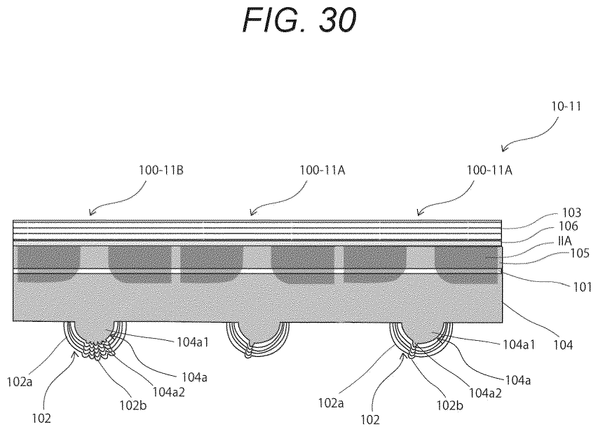

Hereinafter, a surface emitting element according to Example 11 of an embodiment of the present technology will be described with reference to the drawings. FIG. 29 is a plan view of a surface emitting element 10-11 according to Example 11 of an embodiment of the present technology. FIG. 30 is a cross-sectional view taken along line P-P of FIG. 29.

As illustrated in FIGS. 29 and 30, the surface emitting element 10-11 is a surface emitting laser array in which a plurality of element portions 100-11 (100-11A and 100-11B) is arranged in an array. The plurality of element portions 100-11 includes at least two element portions 100-11 having different numbers of special structures 102b.

Of the at least two element portions 100-11, the element portion 100-11B (dark gray circle in FIG. 29) which is the element portion 100-11 having the largest number of special structures 102b is arranged on the outer peripheral side of the array, and the element portion 100-11A (light gray circle in FIG. 29) which is the element portion 100-11 having the smallest number of special structures 102b is arranged on the inner peripheral side of the array.

As an example, the plurality of element portions 100-11 is arranged in a matrix (for example, 5×5), a plurality of (for example, nine) element portions 100-11A is arranged on the inner peripheral side, and a plurality of (for example, 16) element portions 100-11B is arranged on the outermost periphery.

As illustrated in FIG. 30, each element portion 100-11A has, for example, one special structure 102b in the vicinity of the top portion of the concave mirror 102. Note that the at least one element portion 100-11A may not have the special structure 102b. As an example, in each element portion 100-11A, the height of the convex surface structure 104al is 10 μm, the diameter of the protrusion 104a2 is 0.3 μm, and the height is 60 nm.

In each element portion 100-11B, the concave mirror 102 has at least five (for example, five) special structures 102b at the top portion, and the optical loss is large and laser oscillation does not occur. That is, each element portion 100-11B is a dummy element. As an example, in each element portion 100-11B, the height of the convex surface structure 104al is 10 μm, the diameter of the protrusion 104a2 is 0.3 μm, and the height is 60 nm.

As an example, the surface emitting element 10-11 can be manufactured by simultaneously generating a plurality of surface emitting laser arrays in which a plurality of element portions 100-11 is two-dimensionally arranged on one wafer (for example, an n-GaN substrate) serving as a base material of the intermediate layer 104, and separating a plurality of continuous integrated surface emitting laser arrays by dicing to form a plurality of chip-shaped surface emitting laser arrays.

According to the surface emitting element 10-11, it is possible to realize a surface emitting laser array in which a plurality of element portions 100-11 having special characteristics is arranged in an array. In addition, for example, when the convex surface structure is smoothed by polishing as described in WO 2020/184148 A, the uniformity of the height of the protruding convex surface structure of the element portion 100-11 on the inner peripheral side of the array is improved. In addition, since the polishing material is most likely to gather on the protrusion of the protruding convex surface structure on the outermost peripheral portion of the array when the above-described polishing is performed, the protruding convex surface structure is more likely to be scraped than the protruding convex surface structure on the inner peripheral side of the array. Therefore, the protruding convex surface structure of the element portion in the outermost peripheral portion has many protrusions so that the element portion becomes a dummy element that does not contribute to light emission, whereby the height of the protruding convex surface structure of the element portion on the inner peripheral side that becomes the light emitting portion can be made uniform. In addition, since the polishing material is likely to be accumulated in the outermost peripheral portion, many protrusions are likely to be formed in the convex surface structure, and the element portion in the outermost peripheral portion can be made a dummy element relatively easily. In addition, since the current concentrates on the outermost peripheral element portion 100-11, the occurrence of the luminance unevenness can be suppressed.

Note that, although illustration of the anode electrode 107 and the cathode electrode 108 is omitted in FIG. 30, the anode electrode 107 and the cathode electrode 108 may be provided in common in the plurality of element portions 100-11 and may be collectively driven, or the anode electrode 107 and/or the cathode electrode 108 may be provided for each element portion 100-11 and each element portion 100-11 may be independently driven.

### 12. Surface Emitting Element According to Example 12 of Embodiment of Present Technology

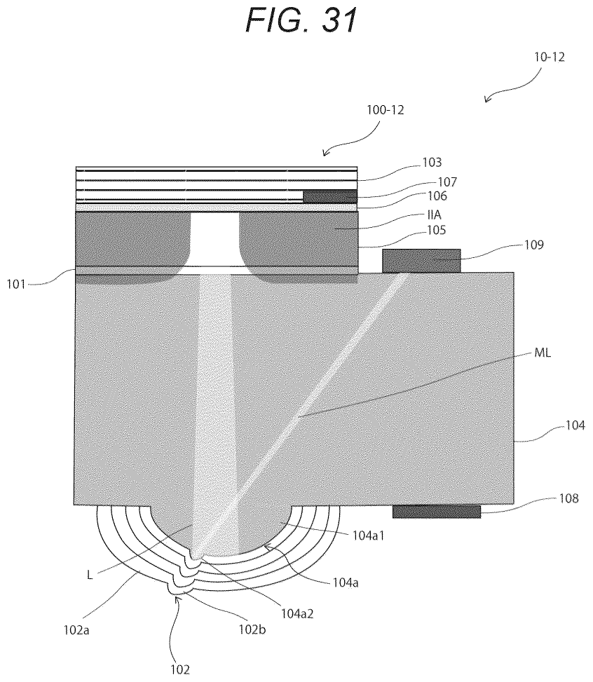

Hereinafter, a surface emitting element according to Example 12 of an embodiment of the present technology will be described with reference to the drawings. FIG. 31 is a cross-sectional view of a surface emitting element 10-12 according to Example 12 of an embodiment of the present technology.

As illustrated in FIG. 31, the surface emitting element 10-12 has a configuration similar to the surface emitting element 10-1 according to Example 1 except that the concave mirror 102 of the element portion 100-12 has one special structure 102b and has a light receiving element 109 that receives light emitted from the light emitting layer 101 and passing through the special structure 102b. The light receiving element 109 includes, for example, a photodiode (PD), and is provided on the upper surface of the intermediate layer 104.

In the surface emitting element 10-12, the light reflected by the special structure 102b among the light L emitted from the light emitting layer 101 is received by the light receiving element 109 as the monitor light ML, and the light amount of the element portion 100-12 can be controlled (for example, automatic power control) on the basis of the received light amount.

According to the surface emitting element 10-12, it is possible to realize a surface emitting laser in which the element portion 100-12 and the light receiving element 109 for monitoring a light amount are integrated in a monolithic manner.

### 13. Surface Emitting Element According to Example 13 of Embodiment of Present Technology

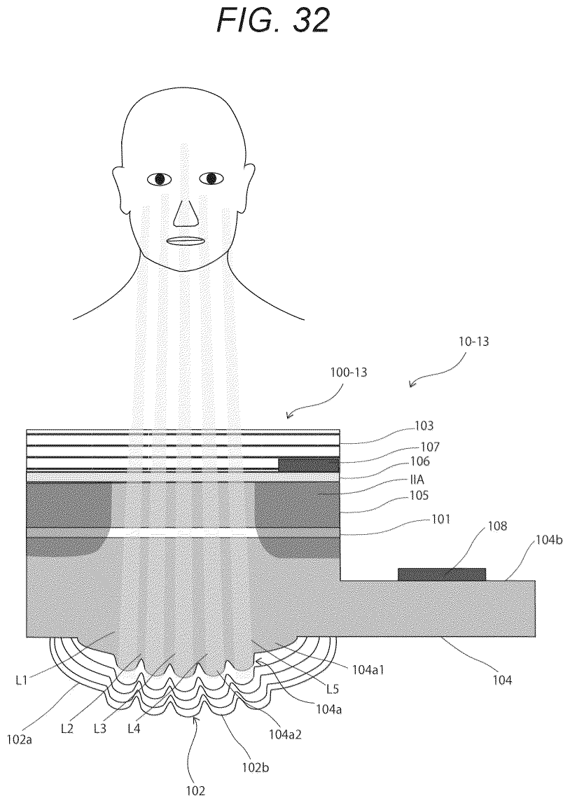

Hereinafter, a surface emitting element according to Example 13 of an embodiment of the present technology will be described with reference to the drawings. FIG. 32 is a cross-sectional view of a surface emitting element 10-13 according to Example 13 of an embodiment of the present technology.

The surface emitting element 10-13 has a configuration substantially similar to the surface emitting element 10-1 according to Example 1 except that a plurality of (for example, five) special structures 102b is provided in an array on the concave mirror body 102a in the element portion 100-13.

In the surface emitting element 10-13, as an example, the convex surface structure 104al has a diameter of 80 μm, a height of 2 μm, and a curvature radius of 650 nm, and the protrusion 104a2 has a diameter of 4 μm, a height of 60 nm, a curvature radius of 33 μm, and a current confinement diameter of 8 μm. The number of the protrusions 104a2 is, for example, five.

In the surface emitting element 10-13, since the special structure 102b functions as a minute optical element, the horizontal mode becomes the multi-mode, and a plurality of (for example, five) beams L1 to L5 are emitted from the element portion 100-13. The shape and depth of the target object can be obtained from the degree of distortion of the pattern by irradiating the target object with the plurality of beams L1 to L5 (structured light).

Structured light can be implemented using a light emitting and receiving device including a surface emitting element 10-13 that emits a plurality of light via a plurality of special structures 102b and a light receiving element (for example, a PD array) that receives a plurality of light emitted from the surface emitting element 10-13 and reflected by an object.

### 14. Surface Emitting Element According to Example 14 of Embodiment of Present Technology

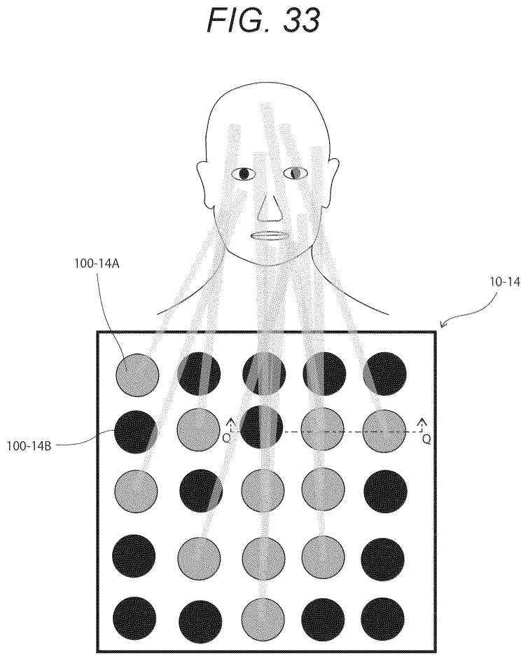

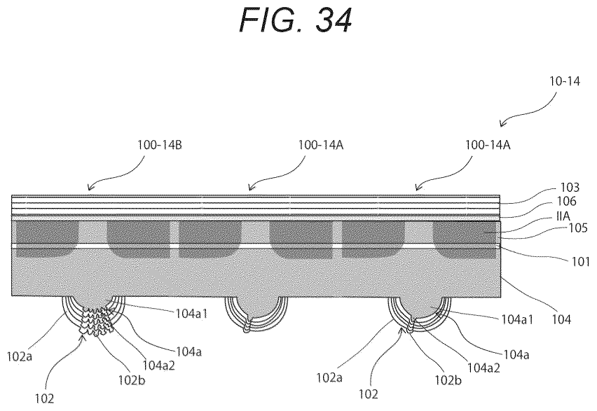

Hereinafter, a surface emitting element according to Example 14 of an embodiment of the present technology will be described with reference to the drawings. FIG. 33 is a cross-sectional view of a surface emitting element 10-14 according to Example 14 of an embodiment of the present technology. FIG. 34 is a cross-sectional view taken along line Q-Q in FIG. 33.

As illustrated in FIGS. 33 and 34, the surface emitting element 10-14 is a surface emitting laser array in which a plurality of element portions 100-14 (100-14A and 100-14B) is arranged in an array. The plurality of element portions 100-14 includes at least two element portions 100-14 having different numbers of special structures 102b.

As an example, the plurality of element portions 100-14 is arranged in a matrix (for example, 5×5), and among at least two element portions 100-14 having different numbers of special structures 102b, an element portion 100-14B (dark gray circle in FIG. 33) that is the element portion 100-14 having the largest number of special structures 102b and an element portion 100-14A (light gray circle in FIG. 33) that is the element portion 100-14 having the smallest number of special structures 102b are randomly arranged in the array. Note that the plurality of element portions 100-14 may be regularly arranged in the array.

As illustrated in FIG. 34, each element portion 100-14A has one special structure 102b having curvature near the top portion of the concave mirror 102. Note that the at least one element portion 100-14A may not have the special structure 102b. As an example, in each element portion 100-14A, the height of the convex surface structure 104al is 10 μm, the curvature radius is 33 μm, the diameter of the protrusion 104a2 is 0.4 μm, and the height is 60 nm.

Each element portion 100-14B has at least three (for example, five) special structures 102b (for example, polygonal structures) having no curvature in the vicinity of the top portion of the concave mirror 102, and has a large optical loss and does not perform laser oscillation. That is, each element portion 100-14B is a dummy element. As an example, in each element portion 100-14B, the height of the convex surface structure 104al is 10 μm, the diameter of the protrusion 104a2 is 0.3 μm, and the height is 60 nm.

As an example, the surface emitting element 10-14 can be manufactured by simultaneously generating a plurality of surface emitting laser arrays in which a plurality of element portions 100-14 is two-dimensionally arranged on one wafer (for example, an n-GaN substrate) serving as a base material of the intermediate layer 104, and separating a plurality of continuous integrated surface emitting laser arrays by dicing to form a plurality of chip-shaped surface emitting laser arrays.

According to the surface emitting element 10-14, it is possible to realize a surface emitting laser array in which a plurality of element portions 100-14 having special characteristics is arranged in an array.

Note that, although illustration of the anode electrode 107 and the cathode electrode 108 is omitted in FIG. 33, the anode electrode 107 and the cathode electrode 108 may be provided in common in the plurality of element portions 100-14 and may be collectively driven, or the anode electrode 107 and/or the cathode electrode 108 may be provided for each element portion 100-14 and each element portion 100-14 may be independently driven.

In the surface emitting element 10-14, since the special structure 102b functions as a minute optical element in the element portion 100-14A, the horizontal mode becomes the multi-mode, and a plurality of beams is emitted from the element portion 100-14A. The shape and depth of the target object can be obtained from the degree of distortion of the pattern by irradiating the target object with the plurality of beams (structured light).

Structured light can be performed using a light emitting and receiving device including a surface emitting element 10-14 that emits a plurality of light from a plurality of element portions 100-14A and a light receiving element (for example, a PD array) that receives light emitted from the surface emitting element 10-14 and reflected by an object.

### 15. Surface Emitting Element According to Example 15 of Embodiment of Present Technology

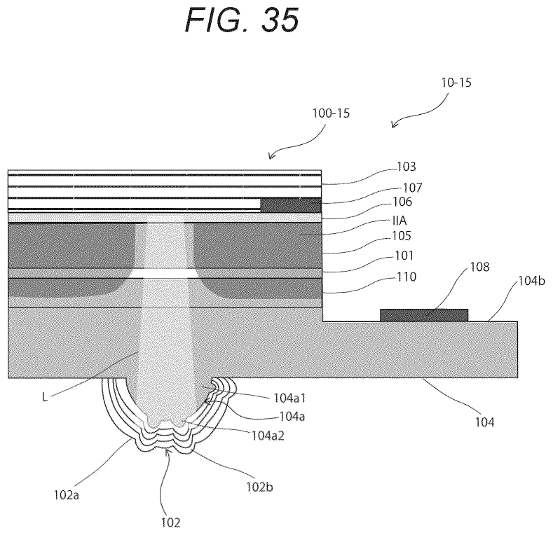

Hereinafter, a surface emitting element according to Example 15 of an embodiment of the present technology will be described with reference to the drawings. FIG. 35 is a cross-sectional view of a surface emitting element 10-15 according to Example 15 of an embodiment of the present technology.

The surface emitting element 10-15 has a configuration substantially similar to the surface emitting element 10-4 according to Example 4 except that the intermediate layer 104, the light emitting layer 101, and the first and second cladding layers 110 and 105 sandwiching the light emitting layer 101 are constituted by an AlGaAs-based compound semiconductor.

As an example, the element portion 100-15 of the surface emitting element 10-15 includes an n-GaAs substrate as the intermediate layer 104, an active layer constituted by an AlGaAs-based compound semiconductor as the light emitting layer 101, an n-AlGaAs layer as the first cladding layer 110, and a p-AlGaAs layer as the second cladding layer 105.

In the element portion 100-15, the reflector 103 may be a semiconductor multilayer film reflector constituted by, for example, an AlGaAs-based compound semiconductor, or may be a dielectric multilayer film reflector.

In the element portion 100-15, the concave mirror 102 may be, for example, either a dielectric multilayer film reflector or a semiconductor multilayer film reflector, but a dielectric multilayer film reflector capable of obtaining high reflectance while reducing the thickness is preferable.

In the element portion 100-15, the ion implantation region IIA as the current confinement portion is constituted by, for example, Zn, H, O, or the like.

The surface emitting element 10-15 also performs substantially an operation similar to the surface emitting element 10-1 according to Example 1.

### <<Method for Manufacturing Surface Emitting Element>>

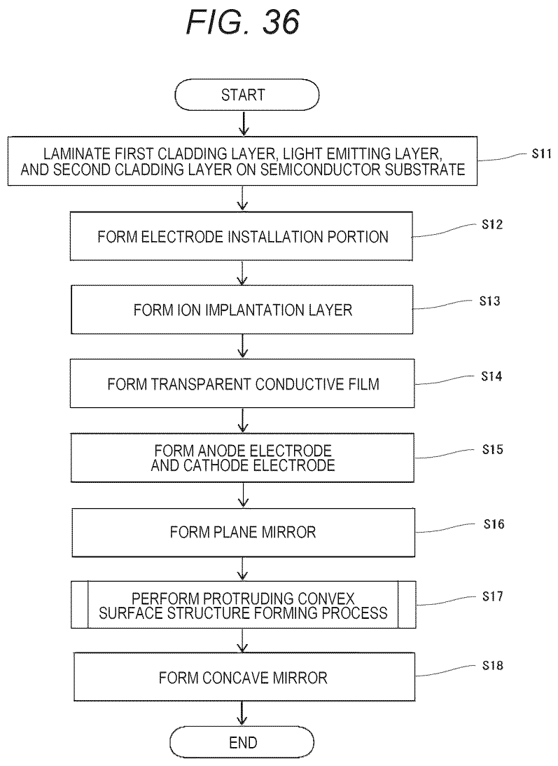

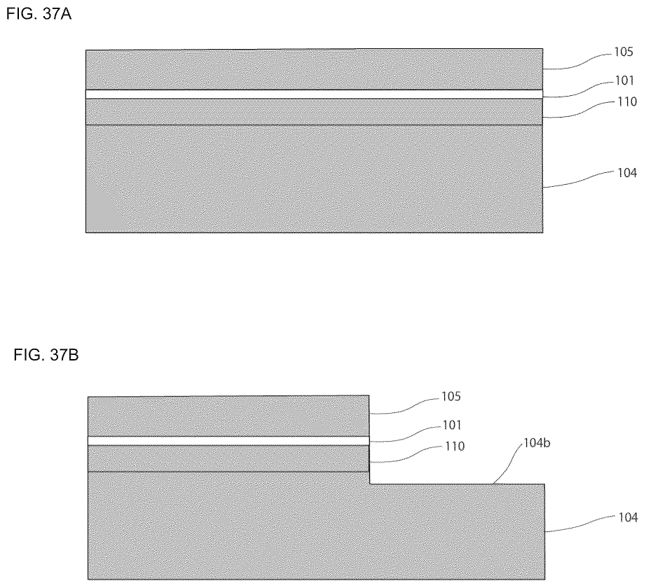

Hereinafter, a method for manufacturing the surface emitting element 10-15 will be described with reference to the flowchart of FIG. 36 and the cross-sectional views of FIGS. 37A to 40B. Here, as an example, a plurality of surface emitting elements 10-15 is simultaneously generated on one wafer (semiconductor substrate (for example, n-GaAs substrate)) as a base material of the intermediate layer 104. Subsequently, the plurality of continuous integrated surface emitting elements 10-15 is separated from each other to obtain the plurality of chip-shaped surface emitting elements (surface emitting element chips).

### (Step S11)

In step S11, the first cladding layer 110, the light emitting layer 101, and the second cladding layer 105 are laminated on the semiconductor substrate (see FIG. 37A). Specifically, the first cladding layer 110, the light emitting layer 101, and the second cladding layer 105 are laminated in this order on the semiconductor substrate to be the intermediate layer 104 in the growth chamber by a metal organic chemical vapor deposition method (MOCVD method) or a molecular beam epitaxy method (MBE method) to generate a laminate.

### (Step S12)

In step S12, the electrode installation portion 104b is formed (see FIG. 37B). Specifically, a resist pattern covering a position other than the position where the electrode installation portion 104b is formed on the laminate is formed, and the laminate is etched using the resist pattern as a mask. At this time, etching is performed until the semiconductor substrate to be the intermediate layer 104 is exposed. As a result, the cutaway electrode installation portion 104b is formed in the laminate.

### (Step S13)

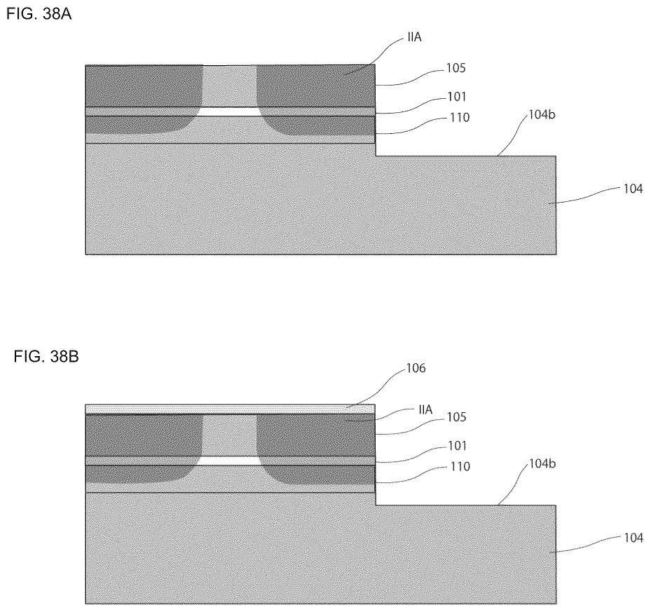

In step S13, the ion implantation region IIA is formed (see FIG. 38A). Specifically, a protective film constituted by resist, SiO₂, or the like is formed to cover a portion other than the position where the ion implantation region IIA is formed on the laminate, and ions (for example, H++) are implanted into the laminate from the second cladding layer 105 side using the protective film as a mask. At this time, the implantation depth of the ion implantation is assumed to reach the first cladding layer 110.

### (Step S14)

In step S14, the transparent conductive film 106 is formed (see FIG. 38B). Specifically, the transparent conductive film 106 is formed on the second cladding layer 105 by, for example, a vacuum vapor deposition method, sputtering, or the like.

### (Step S15)

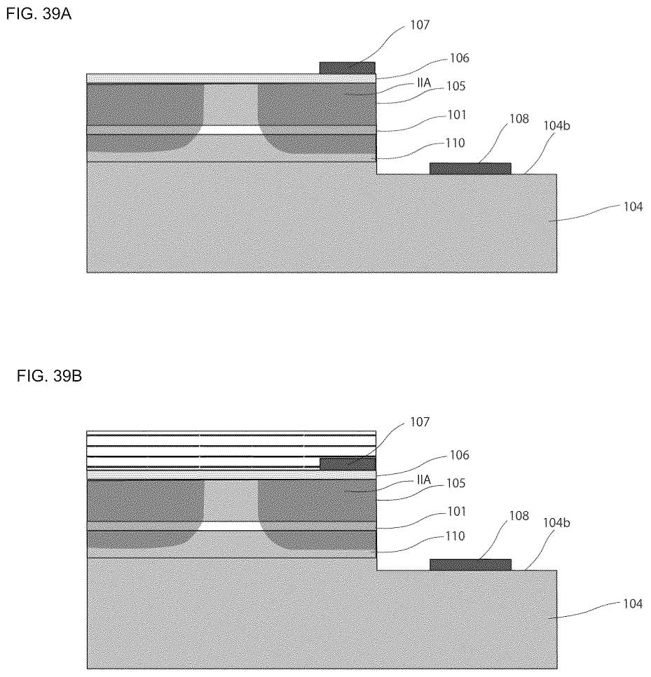

In step S15, the anode electrode 107 and the cathode electrode 108 are formed (see FIG. 39A). Specifically, the anode electrode 107 and the cathode electrode 108 are formed using, for example, a lift-off method.

### (Step S16)

In step S16, a plane mirror as the reflector 103 is formed (see FIG. 39B). Specifically, a semiconductor multilayer film reflector or a dielectric multilayer film to be the reflector 103 is formed on the transparent conductive film 106 by, for example, a vacuum vapor deposition method, a sputtering method, a CVD method, or the like.

### (Step S17)

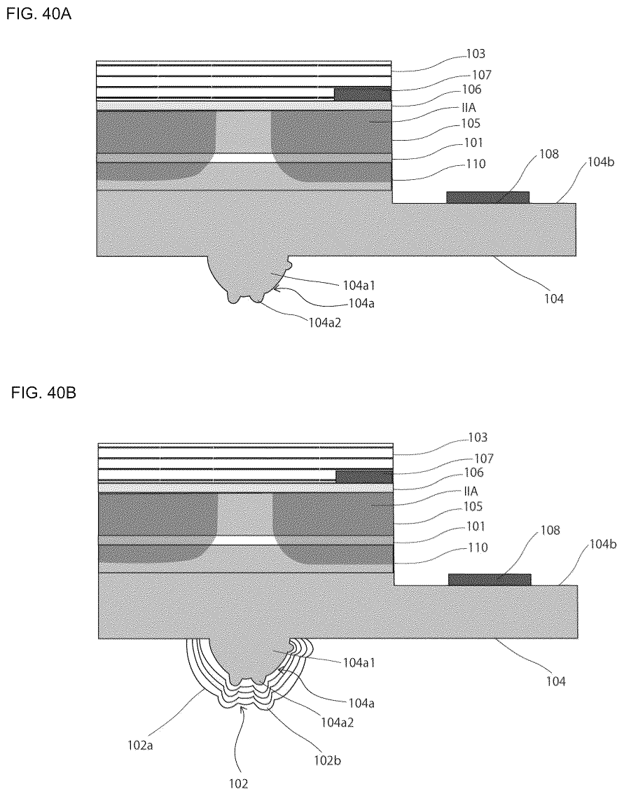

In step S17, a protruding convex surface structure forming process 1 (see FIG. 4), which is an example of the protruding convex surface structure forming process, is performed (see FIG. 40A).

### (Step S18)

In step S18, the concave mirror 102 is formed (see FIG. 40B). Specifically, the material of the concave mirror 102 (for example, a dielectric multilayer film) is formed on the protruding convex surface structure 104a by, for example, a vacuum vapor deposition method, a sputtering method, a CVD method, or the like. As a result, the concave mirror 102 having a shape following the protruding convex surface structure 104a is formed. As a result, a plurality of surface emitting elements 10-15 is generated on a wafer (semiconductor substrate (for example, n-GaAs substrate)). Thereafter, the plurality of continuous integrated surface emitting elements 10-15 is separated by dicing to obtain chip-shaped surface emitting elements 10-15 (surface emitting element chips). The surface emitting element 10-15 is mounted on, for example, a CAN package. More specifically, the surface of the surface emitting element 10-15 on the concave mirror 102 side is soldered to the CAN package.

According to the surface emitting element 10-15, an effect similar to that of the surface emitting element 10-4 according to Example 4 can be obtained.

### 16. Surface Emitting Element According to Example 16 of Embodiment of Present Technology

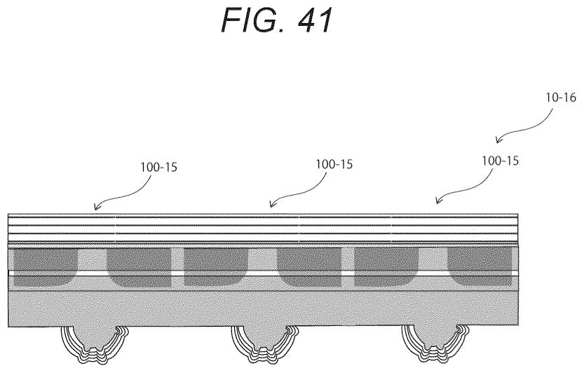

Hereinafter, a surface emitting element according to Example 16 of an embodiment of the present technology will be described with reference to the drawings. FIG. 41 is a cross-sectional view of a surface emitting element 10-16 according to Example 16 of an embodiment of the present technology.

As illustrated in FIG. 41, the surface emitting element 10-16 is a surface emitting laser array in which a plurality of element portions 100-15 of the surface emitting element 10-15 according to Example 15 is arranged in an array.

As an example, the pitch (center interval) of the plurality of element portions 100-15 in the surface emitting element 10-16 is several tens of μm (for example, 25 μm). The plurality of element portions 100-15 may be arranged in a hexagonal close-packed array.

In the surface emitting element 10-16, the plane orientation of the substrate as the intermediate layer 104 is not particularly limited. The oscillation wavelength of each element portion 100-15 of the surface emitting element 10-16 is, for example, 780 nm.

As an example, the surface emitting element 10-16 can be manufactured by simultaneously generating a plurality of surface emitting laser arrays in which a plurality of element portions 100-15 is two-dimensionally arranged on one wafer (for example, an n-GaAs substrate) serving as a base material of the intermediate layer 104, and separating a plurality of continuous integrated surface emitting laser arrays by dicing to form a plurality of chip-shaped surface emitting laser arrays.

According to the surface emitting element 10-16, it is possible to realize a surface emitting laser array in which a plurality of element portions 100-15 having special characteristics is arranged in an array.

Note that, although illustration of the anode electrode 107 and the cathode electrode 108 is omitted in FIG. 41, the anode electrode 107 and the cathode electrode 108 may be provided in common in the plurality of element portions 100-15 and may be collectively driven, or the anode electrode 107 and/or the cathode electrode 108 may be provided for each element portion 100-15 and each element portion 100-15 may be independently driven.

### 17. Surface Emitting Element According to Example 17 of Embodiment of Present Technology

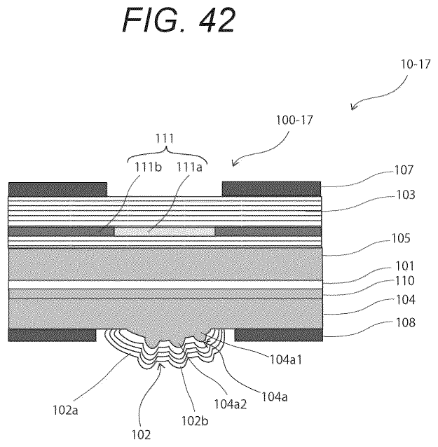

Hereinafter, a surface emitting element according to Example 17 of an embodiment of the present technology will be described with reference to the drawings. FIG. 42 is a cross-sectional view of a surface emitting element 10-17 according to Example 17 of an embodiment of the present technology.

The surface emitting element 10-17 has a configuration substantially similar to the surface emitting element 10-4 according to Example 4 except that the element portion 100-17 is constituted by an AlGaAs-based compound semiconductor, and the intermediate layer 104, the light emitting layer 101, the first and second cladding layers 110 and 105 sandwiching the light emitting layer 101, and the reflector 103 are constituted by an AlGaAs-based compound semiconductor.

As an example, the element portion 100-17 of the surface emitting element 10-17 includes an n-GaAs substrate as the intermediate layer 104, an active layer constituted by an AlGaAs-based compound semiconductor, an n-AlGaAs layer as the first cladding layer 110, and a p-AlGaAs layer as the second cladding layer 105.

In the element portion 100-17, the reflector 103 may be a semiconductor multilayer film reflector constituted by, for example, an AlGaAs-based compound semiconductor, or may be a dielectric multilayer film reflector.

In the element portion 100-17, the concave mirror 102 may be, for example, either a dielectric multilayer film reflector or a semiconductor multilayer film reflector, but a dielectric multilayer film reflector capable of obtaining high reflectance while reducing the thickness is preferable.

The element portion 100-17 includes an oxidation confinement layer 111. As an example, the oxidation confinement layer 111 is disposed inside the reflector 103. As an example, the oxidation confinement layer 111 includes a non-oxidized region 111a constituted by AlAs and an oxidized region 111b constituted by an oxide of AlAs (for example, Al₂O₃) surrounding the non-oxidized region 111a. In the oxidation confinement layer 111, the non-oxidized region 111a serves as a current/light passage region, and the oxidized region 111b serves as a current/light confinement region.

In the surface emitting element 10-17, the anode electrode 107 is provided in a frame shape (for example, a ring shape) on the upper surface of the reflector 103. An inner diameter side of the anode electrode 107 is an emission port.

In the surface emitting element 10-17, the cathode electrode 108 is provided on the back surface of the intermediate layer 104 so as to surround the concave mirror 102.

The surface emitting element 10-17 also performs substantially an operation similar to the surface emitting element 10-1 according to Example 1.

### <<Method for Manufacturing Surface Emitting Element>>

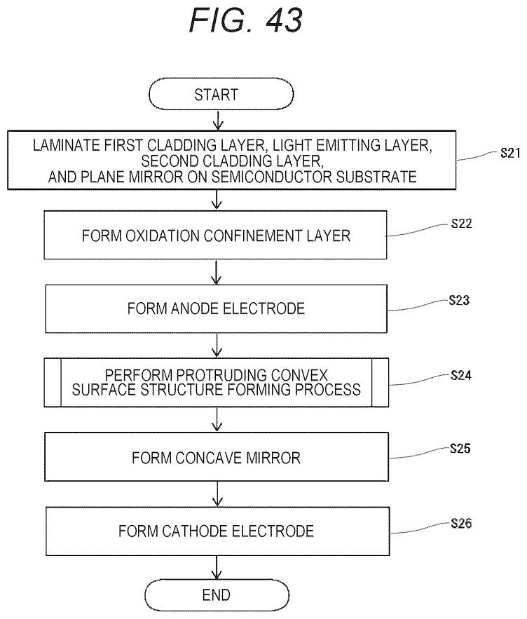

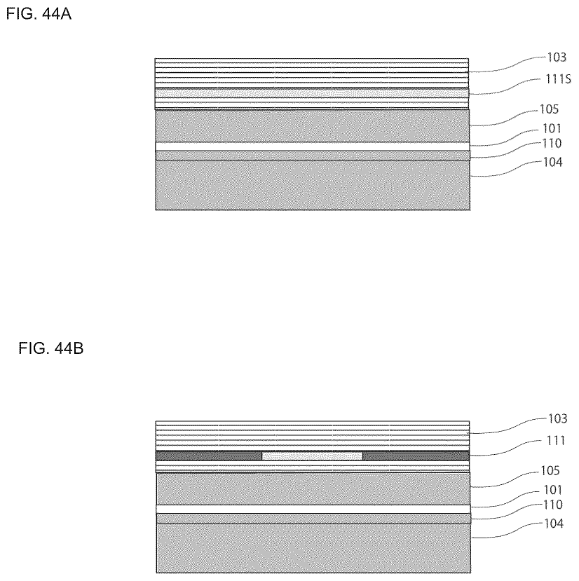

Hereinafter, a method for manufacturing the surface emitting element 10-17 will be described with reference to the flowchart of FIG. 43 and the cross-sectional views of FIGS. 44A to 46B. Here, as an example, a plurality of surface emitting elements 10-17 is simultaneously generated on one wafer (semiconductor substrate (for example, n-GaAs substrate)) as a base material of the intermediate layer 104. Subsequently, the plurality of continuous integrated surface emitting elements 10-17 is separated from each other to obtain the plurality of chip-shaped surface emitting elements (surface emitting element chips).

### (Step S21)

In step S21, a plane mirror as the first cladding layer 110, the light emitting layer 101, the second cladding layer 105, and the reflector 103 is laminated on the semiconductor substrate (see FIG. 44A). Specifically, by metal organic chemical vapor deposition method (MOCVD method) or molecular beam epitaxy method (MBE method), the first cladding layer 110, the light emitting layer 101, the second cladding layer 105, and a plane mirror as the reflector 103 including the selected oxidized region 111S are laminated in this order on the semiconductor substrate to be the intermediate layer 104 in the growth chamber to generate a laminate.

### (Step S22)

In step S22, the oxidation confinement layer 111 is formed (see FIG. 44B). Specifically, the laminate is exposed to a water vapor atmosphere to oxidize (selectively oxidize) the selected oxidized region 111S from the side surface, thereby forming the oxidation confinement layer 111 in which the non-oxidized region 111a is surrounded by the oxidized region 111b.

### (Step S23)

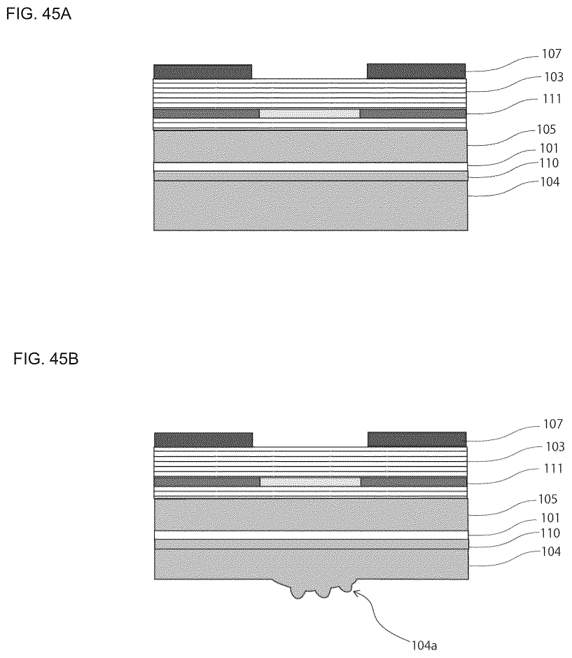

In step S23, the anode electrode 107 is formed (see FIG. 45A). Specifically, the frame-shaped (for example, ring-shaped) anode electrode 107 is formed on the reflector 103 by, for example, a lift-off method.

### (Step S24)

In step S24, a protruding convex surface structure forming process 1 (see FIG. 4), which is an example of the protruding convex surface structure forming process, is performed (see FIG. 45B).

### (Step S25)

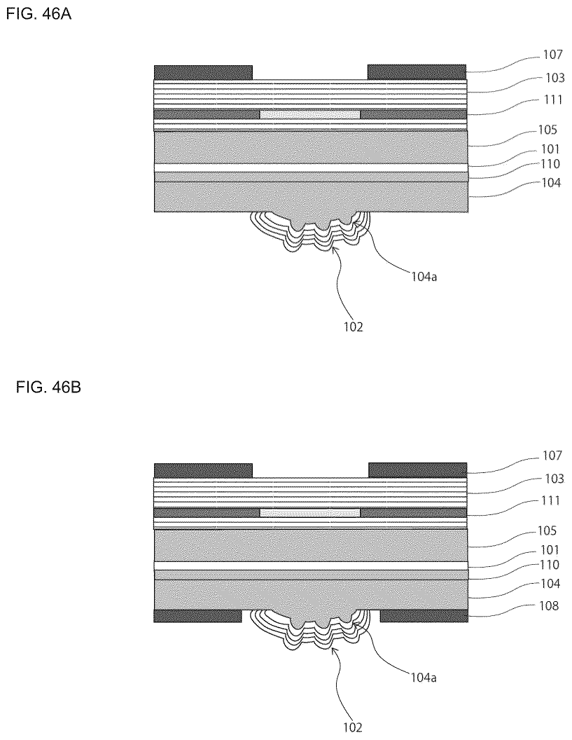

In step S25, the concave mirror 102 is formed (see FIG. 46A). Specifically, the material of the concave mirror 102 (for example, a dielectric multilayer film) is formed on the protruding convex surface structure 104a by, for example, a vacuum vapor deposition method, a sputtering method, a CVD method, or the like. As a result, the concave mirror 102 having a shape following the protruding convex surface structure 104a is formed. As a result, a plurality of surface emitting elements 10-17 is generated on a wafer (semiconductor substrate (for example, n-GaAs substrate)). Thereafter, the plurality of continuous integrated surface emitting elements 10-17 is separated by dicing to obtain chip-shaped surface emitting elements 10-17 (surface emitting element chips). The surface emitting element 10-17 is mounted on, for example, a CAN package. More specifically, the surface of the surface emitting element 10-17 on the concave mirror 102 side is soldered to the CAN package.

### (Step S26)

In step S26, the cathode electrode 108 is formed (see FIG. 46B). Specifically, for example, a lift-off method is used to form the frame-shaped (for example, ring-shaped) cathode electrode 108 on the back surface of the intermediate layer 104 so as to surround the concave mirror 102.

According to the surface emitting element 10-17, an effect similar to that of the surface emitting element 10-4 according to Example 4 can be obtained.

### 18. Surface Emitting Element According to Example 18 of Embodiment of Present Technology

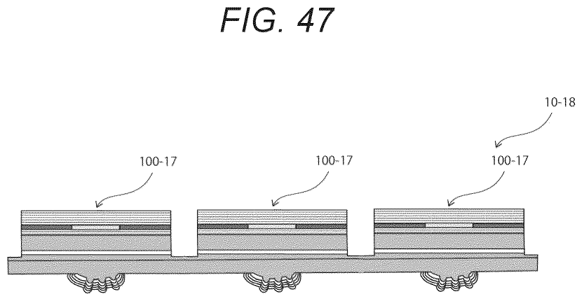

Hereinafter, a surface emitting element according to Example 18 of an embodiment of the present technology will be described with reference to the drawings. FIG. 47 is a cross-sectional view of a surface emitting element 10-18 according to Example 18 of an embodiment of the present technology.

As illustrated in FIG. 47, the surface emitting element 10-18 is a surface emitting laser array in which a plurality of element portions 100-17 of the surface emitting element 10-17 according to Example 17 is arranged in an array.

As an example, the pitch (center interval) of the plurality of element portions 100-17 in the surface emitting element 10-18 is several tens of μm (for example, 25 μm). The plurality of element portions 100-17 may be arranged in a hexagonal close-packed array.

In the surface emitting element 10-18, the plane orientation of the substrate as the intermediate layer 104 is not particularly limited. The oscillation wavelength of the element portion 100-17 of the surface emitting element 10-18 is, for example, 780 nm.

As an example, the surface emitting element 10-18 can be manufactured by simultaneously generating a plurality of surface emitting laser arrays in which a plurality of element portions 100-17 is two-dimensionally arranged on one wafer (for example, an n-GaAs substrate) serving as a base material of the intermediate layer 104, and separating a plurality of continuous integrated surface emitting laser arrays by dicing to form a plurality of chip-shaped surface emitting laser arrays.

According to the surface emitting element 10-18, it is possible to realize a surface emitting laser array in which a plurality of element portions 100-17 having special characteristics is arranged in an array.

Note that, although illustration of the anode electrode 107 and the cathode electrode 108 is omitted in FIG. 47, the anode electrode 107 and the cathode electrode 108 may be provided in common in the plurality of element portions 100-17 and may be collectively driven, or the anode electrode 107 and/or the cathode electrode 108 may be provided for each element portion 100-17 and each element portion 100-17 may be independently driven.

### 19. Variations of Protruding Convex Surface Structure

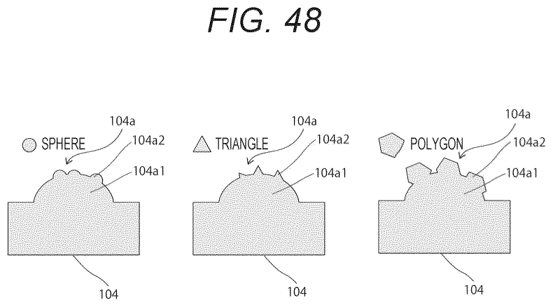

FIG. 48 is a diagram illustrating variations of the protruding convex surface structure. As the shape of the protrusion 104a2 of the protruding convex surface structure 104a formed in the intermediate layer 104, various shapes can be appropriately selected. For example, the cross-sectional shape may be a semicircular shape as in the left diagram of FIG. 48, a triangular shape as in the central diagram of FIG. 48, or a polygonal shape as in the right diagram of FIG. 48.

### 20. Surface Emitting Element According to Modification 1 of Example 1 of Embodiment of Present Technology

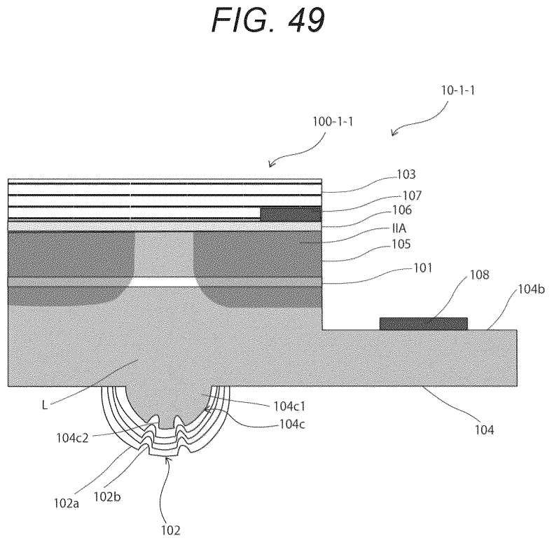

Hereinafter, a surface emitting element according to Modification 1 of Example 1 of an embodiment of the present technology will be described with reference to the drawings. FIG. 49 is a cross-sectional view of a surface emitting element 10-1-1 according to Modification 1 of Example 1 of an embodiment of the present technology.

The surface emitting element 10-1-1 has a configuration substantially similar to the surface emitting element 10-1 according to Example 1 except that the element portion 100-1-1 has a recessed convex surface structure 104c instead of the protruding convex surface structure 104a.

As an example, the recessed convex surface structure 104c has a substantially hemispherical convex surface structure 104cl and at least one (for example, two) recess 104c2 formed on the surface of the convex surface structure 104cl.

As an example, the convex surface structure 104cl has a diameter of 25 μm, a height of 1.3 μm, and a curvature radius of 60 μm. As an example, the recess 104c2 has diameters of 0 and 3 μm and a depth of 60 nm. The recess 104c2 may have any shape such as a semicircular cross section, a triangular cross section, or a polygonal cross section.

In the element portion 100-1-1, the concave mirror 102 has a shape following the recessed convex surface structure 104c. The concave mirror 102 has a special structure 102b including a recess recessed toward the recessed convex surface structure 104c side at a position corresponding to the recess 104c2.

The surface emitting element 10-1-1 performs an operation similar to the surface emitting element 10-1 according to Example 1.

The surface emitting element 10-1-1 can be manufactured by a manufacturing method similar to the method for manufacturing the surface emitting element 10-1 according to Example 1 except that a recessed convex surface structure forming process is performed instead of the protruding convex surface structure forming process. In the recessed convex surface structure forming process, the concave 104c2 is formed in the convex surface structure by photolithography, thereby forming the recessed convex surface structure 104c.

According to the surface emitting element 10-1-1, an effect similar to that of the surface emitting element 10-1 according to Example 1 can be obtained.

### 21. Surface Emitting Element According to Modification 2 of Example 1 of Embodiment of Present Technology

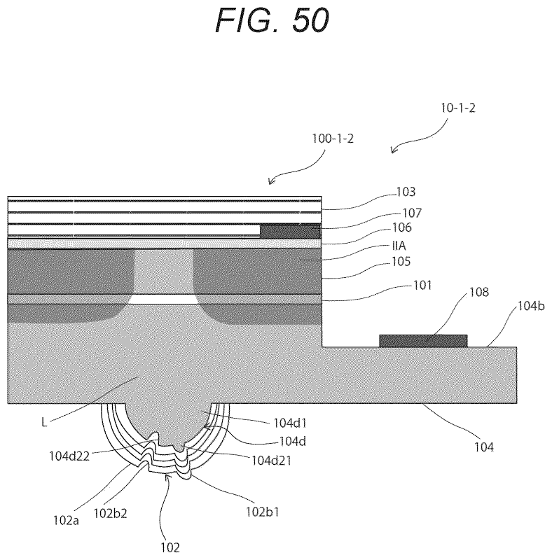

Hereinafter, a surface emitting element according to Modification 2 of Example 1 of an embodiment of the present technology will be described with reference to the drawings. FIG. 50 is a cross-sectional view of a surface emitting element 10-1-2 according to Modification 2 of Example 1 of an embodiment of the present technology.

The surface emitting element 10-1-2 has a configuration substantially similar to the surface emitting element 10-1 according to Example 1 except that the element portion 100-1-2 has a protruding/recessed convex surface structure 104d instead of the protruding convex surface structure 104a.

As an example, the protruding/recessed convex surface structure 104d has a substantially hemispherical convex surface structure 104d1, at least one (for example, one) protrusion 104d21 and at least one (for example, one) recess 104d22 formed on the surface of the convex surface structure 104d1.

As an example, the convex surface structure 104dl has a diameter of 25 μm, a height of 1.3 μm, and a curvature radius of 60 μm. As an example, the protrusion 104d21 has diameters of 0 and 3 μm and a height of 60 nm, for example. As an example, the recess 104d22 has diameters of 0 and 3 μm and a depth of 60 nm. The protrusion 104d21 and the recess 104d22 may have any shape such as a semicircular cross section, a triangular cross section, or a polygonal cross section.

In the element portion 100-1-2, the concave mirror 102 has a shape following the protruding/recessed convex surface structure 104d. The concave mirror 102 has a special structure 102b1 including a protrusion protruding toward the outermost surface side of the concave mirror 102 at a position corresponding to the protrusion 104d21, and has a special structure 102b2 including a recess recessed toward the protruding/recessed convex surface structure 104d at a position corresponding to the recess 104d22.

The surface emitting element 10-1-2 performs an operation similar to the surface emitting element 10-1 according to Example 1.

The surface emitting element 10-1-1 can be manufactured by a manufacturing method similar to the method for manufacturing the surface emitting element 10-1 according to Example 1 except that a protruding/recessed convex surface structure forming process is performed instead of the protruding convex surface structure forming process. In the protruding/recessed convex surface structure forming process, the protrusion 104d21 and the recess 104d22 are formed in the convex surface structure by photolithography, thereby forming the protruding/recessed convex surface structure 104d.

According to the surface emitting element 10-1-2, an effect similar to that of the surface emitting element 10-1 according to Example 1 can be obtained.

### 22. Surface Emitting Element According to Modification of Example 5 of Embodiment of Present Technology

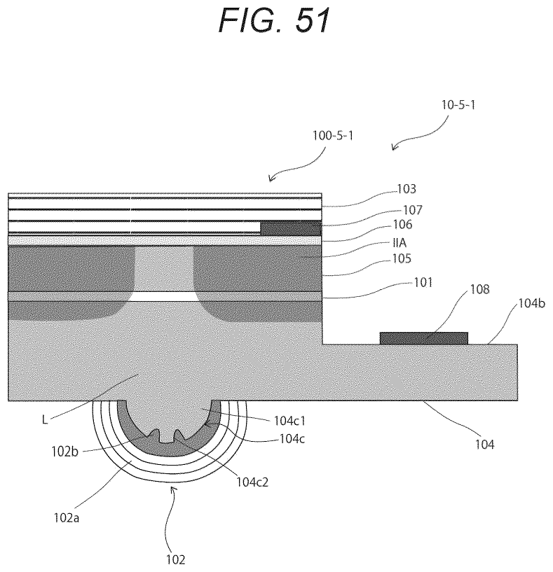

Hereinafter, a surface emitting element according to a modification of Example 5 of an embodiment of the present technology will be described with reference to the drawings. FIG. 51 is a cross-sectional view of a surface emitting element 10-5-1 according to a modification of Example 5 of an embodiment of the present technology.

The surface emitting element 10-5-1 has a configuration substantially similar to the surface emitting element 10-5 according to Example 5 except that the element portion 100-5-1 has a recessed convex surface structure 104c instead of the protruding convex surface structure 104a.

As an example, the recessed convex surface structure 104c has a substantially hemispherical convex surface structure 104cl and at least one (for example, two) recess 104c2 formed on the surface of the convex surface structure 104cl.

As an example, the convex surface structure 104cl has a diameter of 25 μm, a height of 1.3 μm, and a curvature radius of 60 μm. As an example, the recess 104c2 has diameters of 0 and 3 μm and a depth of 60 nm. The recess 104c2 may have any shape such as a semicircular cross section, a triangular cross section, or a polygonal cross section.

In the element portion 100-5-1, the concave mirror 102 has a shape following the recessed convex surface structure 104c. The concave mirror 102 has, at a position corresponding to the recess 104c2, a special structure 102b including a protrusion that protrudes toward the recessed convex surface structure 104c side and enters the recess 104c2.

The surface emitting element 10-5-1 performs an operation similar to the surface emitting element 10-1 according to Example 1.

The surface emitting element 10-5-1 can be manufactured by a manufacturing method similar to the method for manufacturing the surface emitting element 10-5 according to Example 5 except that the recessed convex surface structure forming process is performed instead of the protruding convex surface structure forming process. In the recessed convex surface structure forming process, the concave 104c2 is formed in the convex surface structure by photolithography, thereby forming the recessed convex surface structure 104c.

According to the surface emitting element 10-5-1, an effect similar to that of the surface emitting element 10-5 according to Example 5 can be obtained.

### 23. Surface Emitting Element According to Modification of Embodiment of Present Technology

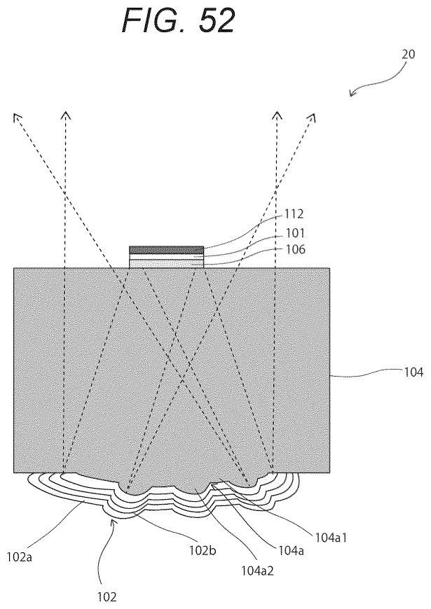

The surface emitting element according to the present technology is not limited to the surface emitting laser, and can be applied to, for example, a light emitting diode (LED). For example, the surface emitting element 20 of the modification illustrated in FIG. 52 has a configuration substantially similar to the surface emitting element 10-1 according to Example 1 except that the reflector 103 and the ion implantation region IIA are not provided and that the electrode member 112 constituted by metal or alloy as the anode electrode is provided. In the surface emitting element 20, the transparent conductive film 106 functions as a cathode electrode. The surface emitting element 20 functions as an LED or a superluminescent diode (SLD). In the surface emitting element 20, when a current is injected into the light emitting layer 101 via the electrode member 112 as an anode electrode, diffused light is emitted from the light emitting layer 101 to the intermediate layer 104 side. This diffused light is emitted to the outside from the surface (upper surface) of the intermediate layer 100 as light (for example, weakly diffused light, parallel light, or focused light) suppressed from spreading by the concave mirror 102. Also in the surface emitting element 20, by the special structure 102b provided in the concave mirror 102, it is possible to obtain an effect other than the effect regarding the laser characteristic obtained in the surface emitting element 10-1 according to Example 1. Note that the array light source may be configured by arranging the surface emitting elements 20 in an array.

### 24. Modifications of Present Technology

The present technology is not limited to the above-described examples and modifications, and various modifications can be made.

The shape, height, diameter, arrangement, and the like of the convex surface structure can be appropriately changed.

The shape, height (or depth), diameter, number, arrangement, and the like of the protrusions or recesses provided in the convex surface structure can be appropriately changed.

The shape, height (or depth), diameter, number, arrangement, and the like of the special structure can be appropriately changed.

In a case where the concave mirror has a plurality of special structures, materials of the special structures may be different from each other.

In a case where the concave mirror has a plurality of special structures, the concave mirror may be arranged regularly or irregularly.

Some of the configurations of the surface emitting elements in each of the examples and the modifications described above may be combined in a range not inconsistent with each other.

In each of the examples and modifications described above, the material, thickness, width, length, shape, size, arrangement, and the like of each component constituting the surface emitting element can be appropriately changed within a range functioning as the surface emitting element.

### 25. Application Examples to Electronic Device

The technology according to the present disclosure (the present technology) can be applied to various products (electronic devices). For example, the technology according to the present disclosure may further be realized as a device (for example, a distance measuring device, a shape recognition device, or the like) to be mounted on any type of moving bodies such as automobiles, electric vehicles, hybrid electric vehicles, motorcycles, bicycles, personal mobilities, airplanes, drones, ships, and robots.

The surface emitting element according to the present technology can also be applied as, for example, a light source or a display itself of a device (for example, a laser printer, a laser copier, a projector, a head-mounted display, a head-up display, or the like) that forms or displays an image by laser light.

The surface emitting element according to the present technology can also be applied to, for example, an individual authentication device. That is, it is also possible to provide an individual authentication device including: a surface emitting element according to the present technology in which a pattern (emission pattern) formed by emitted light is allocated to an individual; and a processing section that receives light from the surface emitting element and performs individual authentication. Specifically, a plurality of surface emitting elements having different convex surface structures and special structures (emission patterns are different from each other) are prepared, emission patterns of the surface emitting elements are allocated to individual living bodies, objects, and the like in advance, and the light receiving section of the processing section is irradiated with light from the surface emitting elements, whereby the individual allocated to the surface emitting elements can be authenticated.

### 26. Example in Which Surface Emitting Element Is Applied to distance measurement device

Hereinafter, application examples of the surface emitting element according to each of the embodiments and modifications described above will be described.

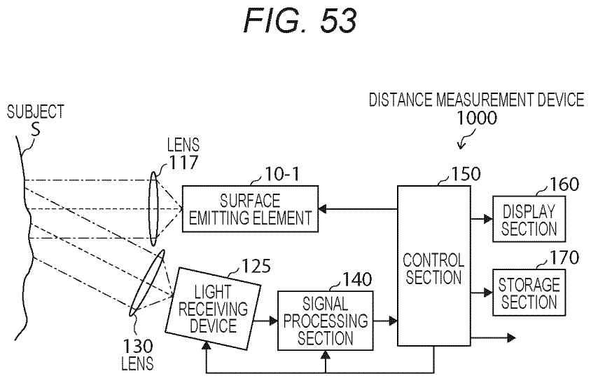

FIG. 53 illustrates an example of a schematic configuration of a distance measurement device 1000 (distance measuring device) including a surface emitting element 10-1 as an example of an electronic device according to the present technology. The distance measurement device 1000 measures the distance to a subject S by a time of flight (TOF) method. The distance measurement device 1000 includes a surface emitting element 10-1 as a light source. The distance measurement device 1000 includes, for example, a surface emitting element 10-1, a light receiving device 125, lenses 117 and 130, a signal processing section 140, a control section 150, a display section 160, and a storage section 170.

The surface emitting element 10-1 is driven by a laser driver (driver). The laser driver has an anode terminal and a cathode terminal connected to an anode electrode and a cathode electrode of the surface emitting element 10-1, respectively, via a wiring. The laser driver includes, for example, circuit elements such as a capacitor and a transistor.

The light receiving device 125 detects light reflected by the subject S. The lens 117 is a lens for collimating the light emitted from the surface emitting element 10-1, and is a collimating lens. The lens 130 is a lens for condensing light reflected by the subject S and guiding the light to the light receiving device 125, and is a condenser lens.

The signal processing section 140 is a circuit for generating a signal corresponding to a difference between a signal input from the light receiving device 125 and a reference signal input from the control section 150. The control section 150 includes, for example, a time to digital converter (TDC). The reference signal may be a signal input from the control section 150, or may be an output signal of a detecting section that directly detects an output of the surface emitting element 10-1. The control section 150 is, for example, a processor that controls the surface emitting element 10-1, the light receiving device 125, the signal processing section 140, the display section 160, and the storage section 170. The control section 150 is a circuit that measures a distance to the subject S on the basis of a signal generated by the signal processing section 140. The control section 150 generates a video signal for displaying information about the distance to the subject S, and outputs the video signal to the display section 160. The display section 160 displays the information regarding the distance to the subject S on the basis of the video signal input from the control section 150. The control section 150 stores information about the distance to the subject S in the storage section 170.

In the present application example, in place of the surface emitting element 10-1, any one of the above-described surface emitting elements 10-2 to 10-18, 10-1-1, 10-1-2, 10-5-1, and 20 can be applied to the distance measurement device 1000. Note that, in a case where a surface emitting element having a plurality of element portions is applied to the distance measurement device 1000, a driver capable of individually driving the plurality of element portions can also be used.

### 27. Example in Which Distance Measurement Device Is Mounted on Moving Body

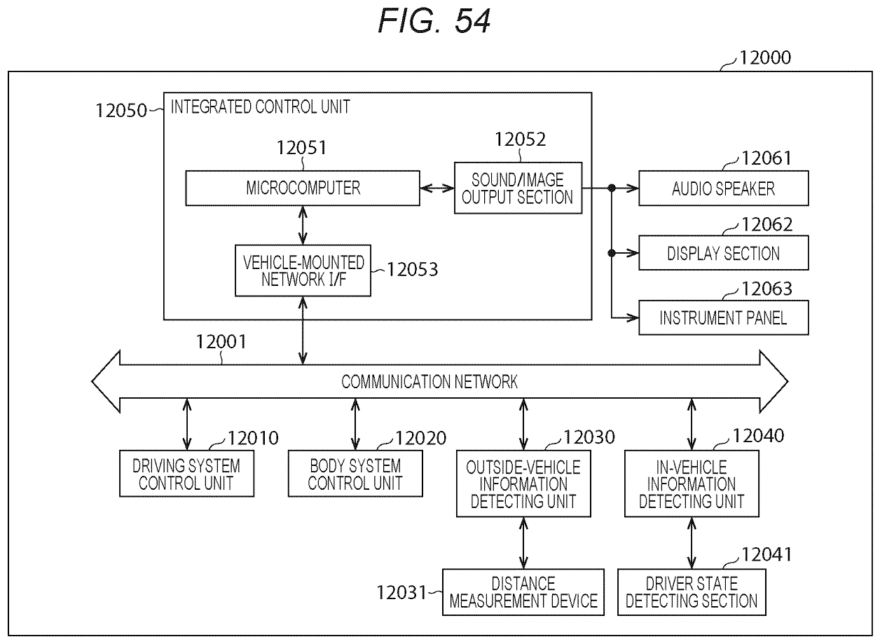

FIG. 54 is a block diagram illustrating a schematic configuration example of a vehicle control system which is an example of a moving body control system to which the technology according to the present disclosure can be applied.

The vehicle control system 12000 includes a plurality of electronic control units connected to each other via a communication network 12001. In the example illustrated in FIG. 54, the vehicle control system 12000 includes a driving system control unit 12010, a body system control unit 12020, an outside-vehicle information detecting unit 12030, an in-vehicle information detecting unit 12040, and an integrated control unit 12050. Further, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information regarding the outside of the vehicle equipped with the vehicle control system 12000. For example, a distance measurement device 12031 is connected to the outside-vehicle information detecting unit 12030. The distance measurement device 12031 includes the distance measurement device 1000 described above. The outside-vehicle information detecting unit 12030 causes the distance measurement device 12031 to measure a distance to an object (subject S) outside the vehicle, and acquires distance data acquired by the measurement. The outside-vehicle information detecting unit 12030 may perform object detection processing of a person, a car, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may discriminate whether the driver is dozing.

The microcomputer 12051 can calculate a control target value for the driving force generating device, the steering mechanism, or the braking device on the basis of the information about the inside or outside of the vehicle acquired by the outside-vehicle information detecting unit 12030 or the in-vehicle information detecting unit 12040, and can output a control command to the driving system control unit 12010. For example, the microcomputer 12051 can perform cooperative control intended to implement functions of an advanced driver assistance system (ADAS), the functions including collision avoidance or impact mitigation for the vehicle, follow-up traveling based on an inter-vehicle distance, vehicle speed maintaining traveling, vehicle collision warning, vehicle lane departure warning, and the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the surroundings of the vehicle acquired by the outside-vehicle information detecting unit 12030 or the in-vehicle information detecting unit 12040.

Further, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 54, an audio speaker 12061, a display section 12062, and an instrument panel 12063 are illustrated as the output device. The display section 12062 may, for example, include at least one of an on-board display and a head-up display.

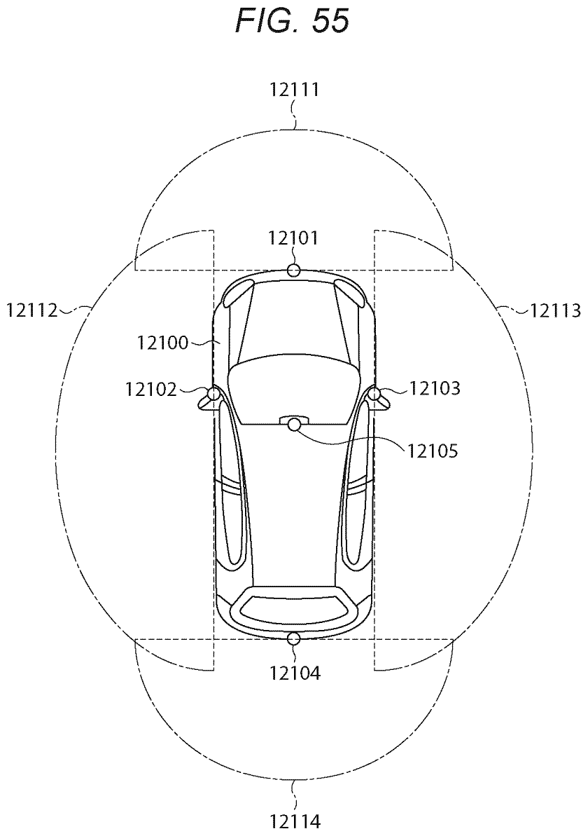

FIG. 55 is a diagram illustrating an example of installation positions of the distance measurement device 12031.

In FIG. 55, a vehicle 12100 includes distance measurement devices 12101, 12102, 12103, 12104, and 12105 as the distance measurement device 12031.

For example, the distance measurement devices 12101, 12102, 12103, 12104, and 12105 are provided at positions such as a front nose, sideview mirrors, a rear bumper, a back door, an upper portion of a windshield in a vehicle interior, and the like of the vehicle 12100. The distance measurement device 12101 provided at the front nose and the distance measurement device 12105 provided at the upper portion of the windshield in the vehicle interior mainly acquire data of the front side of the vehicle 12100. The distance measurement devices 12102 and 12103 provided at the sideview mirrors mainly acquire data of the sides of the vehicle 12100. The distance measurement device 12104 provided at the rear bumper or the back door mainly acquires data of the rear side of the vehicle 12100. The data of the front side acquired by the distance measurement devices 12101 and 12105 is mainly used to detect a preceding vehicle, a pedestrian, an obstacle, a traffic light, a traffic sign, or the like.

Note that FIG. 55 illustrates an example of detection ranges of the distance measurement devices 12101 to 12104. A detection range 12111 indicates a detection range of the distance measurement device 12101 provided at the front nose, detection ranges 12112 and 12113 indicate detection ranges of the distance measurement devices 12102 and 12103 provided at the sideview mirrors, respectively, and a detection range 12114 indicates a detection range of the distance measurement device 12104 provided at the rear bumper or the back door.

For example, the microcomputer 12051 may obtain a distance to each three-dimensional object within the detection ranges 12111 to 12114 and a temporal change in the distance (relative speed with respect to the vehicle 12100) on the basis of the distance data obtained from the distance measurement devices 12101 to 12104, whereby particularly a nearest three-dimensional object present on a traveling path of the vehicle 12100, which travels in substantially the same direction as the vehicle 12100 at a predetermined speed (for example, equal to or more than 0 km/h), may be extracted as a preceding vehicle. Further, the microcomputer 12051 can set a following distance to be maintained in front of a preceding vehicle in advance, and perform automatic brake control (including follow-up stop control), automatic acceleration control (including follow-up start control), or the like. It is thus possible to perform cooperative control intended for automated driving that makes the vehicle travel automatedly without depending on the operation of the driver or the like.

For example, on the basis of the distance data obtained from the distance measurement devices 12101 to 12104, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is higher than or equal to a set value and there is thus a possibility of collision, the microcomputer 12051 can outputs a warning to the driver via the audio speaker 12061 or the display section 12062 and perform forced deceleration or avoidance steering via the driving system control unit 12010 to perform driving assistance for collision avoidance.

An example of the moving body control system to which the technology according to the present disclosure can be applied has been described above. The technology according to the present disclosure may be applied to the distance measurement device 12031 among the configurations described above.

Furthermore, the present technology may also adopt the following configurations.

(1) A surface emitting element including
at least one element portion including:
a light emitting layer; and
a concave mirror disposed on one side of the light emitting layer,
in which the concave mirror includes:
a concave mirror body; and
a structure including a protrusion or a recess.

(2) The surface emitting element according to (1), in which the element portion further includes a reflector disposed on another side of the light emitting layer.

(3) The surface emitting element according to (1) or (2), in which the structure is smaller than the concave mirror body.

(4) The surface emitting element according to any one of (1) to (3), in which the structure has a curvature.

(5) The surface emitting element according to any one of (1) to (4), in which the structure is provided at least on a surface of the concave mirror body farthest from the light emitting layer.

(6) The surface emitting element according to any one of (1) to (5), in which the structure is provided at least on a surface of the concave mirror body closest to the light emitting layer.

(7) The surface emitting element according to any one of (1) to (6), in which a plurality of the structure is disposed in an in-plane direction of the concave mirror body.

(8) The surface emitting element according to any one of (1) to (7), in which a plurality of the structure is disposed in a thickness direction of the concave mirror body.

(9) The surface emitting element according to any one of (1) to (8), in which the concave mirror body and the structure are integrated.

(10) The surface emitting element according to any one of (1) to (8), in which the concave mirror body and the structure are separate bodies.

(11) The surface emitting element according to any one of (1) to (10), in which the element portion further includes an intermediate layer disposed between the concave mirror and the light emitting layer, and the intermediate layer has a convex surface structure corresponding to the concave mirror on a surface on a side of the concave mirror.

(12) The surface emitting element according to (11), in which a portion of the convex surface structure corresponding to the concave mirror body and a portion of the convex surface structure corresponding to the structure are separate bodies.

(13) The surface emitting element according to (11) or (12), in which the concave mirror has an adhesive layer provided with the structure between the concave mirror body and the convex surface structure.

(14) The surface emitting element according to any one of (1) to (13), in which the structure is disposed at a position on an optical path of light from the light emitting layer.

(15) The surface emitting element according to any one of (1) to (13), in which the structure is disposed at a position deviated from an optical path of light from the light emitting layer.

(16) The surface emitting element according to any one of (1) to (15), in which the concave mirror has a plurality of the structure, and the plurality of the structure includes: the structure disposed at a position on an optical path of light from the light emitting layer; and the structure disposed at a position deviated from an optical path of light from the light emitting layer.

(17) The surface emitting element according to any one of (1) to (16), in which a plurality of the element portion is arranged in an array, and the plurality of the element portion includes at least two element portions having different numbers of the structures.

(18) The surface emitting element according to (17), in which an element portion having the largest number of the structures among the at least two element portions is arranged on an outer peripheral side of the array, and an element portion having the smallest number of the structures is arranged on an inner peripheral side of the array.

(19) The surface emitting element according to any one of (1) to (18), in which a plurality of the structure is provided in the concave mirror body in an array.

(20) An individual authentication device including:
the surface emitting element according to any one of (1) to (19) in which a pattern formed by emitted light is assigned to an individual; and
a processing section that receives light from the surface emitting element and performs individual authentication. (21) The surface emitting element according to any one of (1) to (20), in which a curvature radius of a top portion of the concave mirror body is equal to or greater than a resonator length of the surface emitting element.

(22) The surface emitting element according to any one of (1) to (21), further including a light receiving element that receives light emitted from the light emitting layer and passing through the structure.

(23) A light emitting and receiving device including:
the surface emitting element according to (19) that emits a plurality of light through a plurality of the structure; and
a light receiving element that receives a plurality of light emitted from the surface emitting element and reflected by an object.

(24) An electronic device including the surface emitting element according to any one of (1) to (21).

(25) A method for forming a concave mirror, the method including the steps of:
polishing a semiconductor substrate to attach an attached substance constituted by an organic substance or an inorganic substance contained in a polishing material onto the semiconductor substrate;
forming a protrusion in which at least a top portion constituted by a flowable material has a curved surface on the semiconductor substrate;
etching the semiconductor substrate using the protrusion as a mask to form a convex structure in which at least a top portion is a curved surface and a protrusion or a recess is formed on a surface of the semiconductor substrate; and
forming a reflective film on a surface of the convex structure.

(26) A method for manufacturing a surface emitting element, the method including the steps of:
laminating a light emitting layer on one surface side of a semiconductor substrate;
polishing another surface of the semiconductor substrate to attach an attached substance constituted by an organic substance or an inorganic substance contained in a polishing material onto the another surface;
forming a protrusion in which at least a top portion constituted by a flowable material has a curved surface on the another surface;
etching the semiconductor substrate using the protrusion as a mask to form a convex structure in which at least a top portion is a curved surface and a protrusion or a recess is formed on a surface of the semiconductor substrate; and
forming a reflective film on a surface of the convex structure.

### REFERENCE SIGNS LIST

10-1 to 10-18, 10-1-1, 10-1-2, 10-5-1, 20 element
Surface emitting
100-1 to 100-18, 100-1-1, 100-1-2, 100-5-1, 101 Light emitting layer
102 Concave mirror
102a Concave mirror body
102b Special structure (structure)
102c Adhesive layer
103 Reflector
104 Intermediate layer
104a Protruding convex surface structure (convex surface structure)
104c Recessed convex surface structure (convex surface structure)
104d Protruding/recessed convex surface structure (convex surface structure)
109 Light receiving element
L Light from light emitting layer

1. A surface emitting element comprising
at least one element portion including:
a light emitting layer; and
a concave mirror disposed on one side of the light emitting layer,
wherein the concave mirror includes:
a concave mirror body; and
a structure including a protrusion or a recess.

2. The surface emitting element according to claim 1, wherein the element portion further includes a reflector disposed on another side of the light emitting layer.

3. The surface emitting element according to claim 1, wherein the structure is smaller than the concave mirror body.

4. The surface emitting element according to claim 1, wherein the structure has a curvature.

5. The surface emitting element according to claim 1, wherein the structure is provided at least on a surface of the concave mirror body farthest from the light emitting layer.

6. The surface emitting element according to claim 1, wherein the structure is provided at least on a surface of the concave mirror body closest to the light emitting layer.

7. The surface emitting element according to claim 1, wherein a plurality of the structure is disposed in an in-plane direction of the concave mirror body.

8. The surface emitting element according to claim 1, wherein a plurality of the structure is disposed in a thickness direction of the concave mirror body.

9. The surface emitting element according to claim 1, wherein the concave mirror body and the structure are integrated.

10. The surface emitting element according to claim 1, wherein the concave mirror body and the structure are separate bodies.

11. The surface emitting element according to claim 1,
wherein the element portion further includes an intermediate layer disposed between the concave mirror and the light emitting layer, and
the intermediate layer has a convex surface structure corresponding to the concave mirror on a surface on a side of the concave mirror.

12. The surface emitting element according to claim 11, wherein a portion of the convex surface structure corresponding to the concave mirror body and a portion of the convex surface structure corresponding to the structure are separate bodies.

13. The surface emitting element according to claim 11, wherein the concave mirror has an adhesive layer provided with the structure between the concave mirror body and the convex surface structure.

14. The surface emitting element according to claim 1, wherein the structure is disposed at a position on an optical path of light from the light emitting layer.

15. The surface emitting element according to claim 1, wherein the structure is disposed at a position deviated from an optical path of light from the light emitting layer.

16. The surface emitting element according to claim 1,
wherein the concave mirror has a plurality of the structure, and
the plurality of the structure includes:
the structure disposed at a position on an optical path of light from the light emitting layer; and
the structure disposed at a position deviated from an optical path of light from the light emitting layer.

17. The surface emitting element according to claim 1,
wherein a plurality of the element portion is arranged in an array, and
the plurality of the element portion includes at least two element portions having different numbers of the structures.

18. The surface emitting element according to claim 17, wherein an element portion having the largest number of the structures among the at least two element portions is arranged on an outer peripheral side of the array, and an element portion having the smallest number of the structures is arranged on an inner peripheral side of the array.

19. The surface emitting element according to claim 1, wherein a plurality of the structures is provided in the concave mirror body in an array.

20. An individual authentication device comprising:
the surface emitting element according to claim 1 in which a pattern formed by emitted light is assigned to an individual; and
a processing section that receives light from the surface emitting element and performs individual authentication.
